(19) United States
(12) Patent Application Publication
(10) Pub. No.: US 2023/0268355 A1
(43) Pub. Date: Aug. 24, 2023

(54) INTEGRATED CIRCUIT DEVICE AND METHOD FOR FABRICATING THE SAME

(71) Applicants: TAIWAN SEMICONDUCTOR MANUFACTURING COMPANY, LTD., Hsinchu (TW); NATIONAL TAIWAN UNIVERSITY, Taipei (TW)

(72) Inventors: Jih-Chao CHIU, New Taipei City (TW); Chee-Wee LIU, Taipei City (TW)

(73) Assignees: TAIWAN SEMICONDUCTOR MANUFACTURING COMPANY, LTD., Hsinchu (TW); NATIONAL TAIWAN UNIVERSITY, TAIPEI (TW)

(21) Appl. No.: 17/678,094

(22) Filed: Feb. 23, 2022

(51) Int. Cl. H01L 27/12; H01L 29/786; H01L 23/522; H01L 23/528; H01L 29/66; H01L 21/02; H01L 21/56

(52) U.S. Cl. CPC H01L 27/1251; H01L 29/7869; H01L 23/5226; H01L 23/5283; H01L 29/66742; H01L 21/02266; H01L 21/0228; H01L 21/56

(57) ABSTRACT

A method for fabricating an integrated circuit device is provided. The method includes forming a field effect transistor (FET) on a semiconductor substrate; depositing a first dielectric layer over the FET; depositing a first metal-containing dielectric layer over the first dielectric layer; and forming a first thin film transistor (TFT) over the first metal-containing dielectric layer.

### BACKGROUND

The semiconductor industry has experienced rapid growth due to continuous improvement in the integration density of a variety of electronic components (e.g., transistors, diodes, resistors, capacitors, etc.). The improvement in integration density has come from allowing more components (e.g., transistors, diodes, resistors, capacitors, etc.) to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic cross-sectional view of an integrated circuit device according to some embodiments of the present disclosure.

FIG. 1B is an exemplary cross-sectional view showing the configuration of the integrated circuit device of FIG. 1A.

FIG. 2A is a schematic cross-sectional view of an integrated circuit device according to some embodiments of the present disclosure.

FIG. 2B is an exemplary cross-sectional view showing the configuration of the integrated circuit device of FIG. 2A.

FIG. 3 is a schematic cross-sectional view of an integrated circuit device according to some embodiments of the present disclosure.

FIGS. 4-15 illustrate a method for fabricating an integrated circuit device at various intermediate stages of manufacture according to some embodiments of the present disclosure.

FIG. 16 is a graph of water vapor transmission rates (WVTR) of Al₂O₃ and silicon nitride according to some embodiments of the present disclosure.

FIGS. 17 and 18 illustrate a method for fabricating an integrated circuit device at various intermediate stages of manufacture according to some embodiments of the present disclosure.

FIG. 19-21 are exemplary cross-sectional views of an integrated circuit device according to some embodiments of the present disclosure.

FIGS. 22-24 are exemplary cross-sectional views of an integrated circuit device according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For allowing more components to be integrated into a given area, various stacking techniques are developed. One of the stacking techniques is transistor stacking, in which transistor devices are stacked vertically, thereby increasing device density. In some embodiments, it is easier to stack thin film transistors (TFT) than stack complementary metal-oxide semiconductor (CMOS) devices due to epitaxy difficulties of CMOS devices and the low processing temperature of TFTs. As thin semiconductor films of the TFTs are sensitive to hydrogen and/or moisture, the threshold voltages (V_{T}) of the stacked TFTs may be unstable. Another one of the stacking techniques is chiplet stacking, in which dies/chips with different technologies and applications can stack vertically, thereby saving the area and lowering energy consumption.

In some embodiments of the present embodiments, a moisture-resistant isolation layer is disposed between stacked layers, thereby avoiding hydrogen and/or moisture diffusion to the stacked TFTs, which in turn will enhance the stability of the threshold voltages (V_{T}) of the stacked TFTs. The moisture-resistant isolation layer may include ceramics, which may be metal-containing compound materials, such as Al₂O₃, Zr₂O₃, TiO₂, the like, or the combination thereof. The moisture-resistant isolation layer may be disposed between two stacked dies/chips in some embodiments. In some further embodiments of the present embodiments, a moisture-resistant encapsulation layer may be used to encapsulate a die/chip or stacked dies/chips, thereby avoiding hydrogen and/or moisture diffusion.

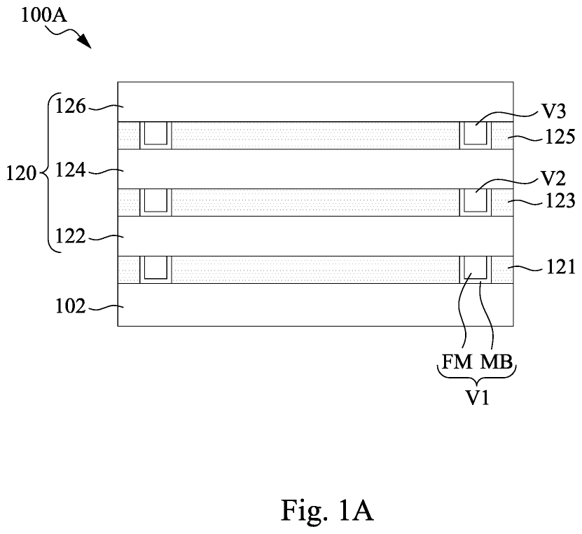

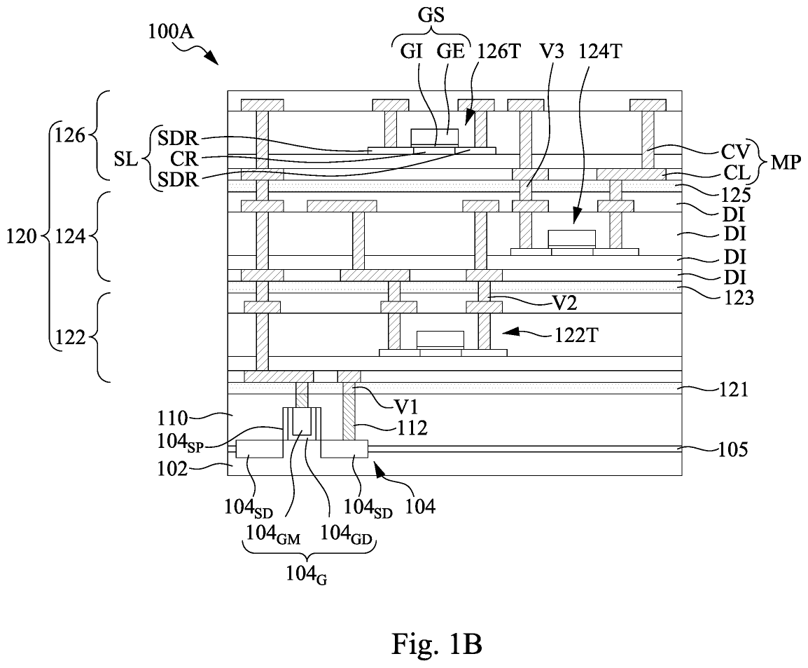

Fig. 1A is a schematic cross-sectional view of an integrated circuit device 100A according to some embodiments of the present disclosure. The integrated circuit device 100A includes a substrate 102 and a back-end-of-line (BEOL) interconnect structure 120 over the substrate 102. In some embodiments, the substrate 102 may be processed through a front-end of line (FEOL) process and have devices (e.g., CMOS field-effect transistors (FETs)) that employs a substantially monocrystalline channel material (e.g., Si) formed over thereon. The BEOL interconnect structure 120 may include plural TFT-based interconnect structures (or interconnect layers) 122, 124, and 126 formed over the substrate 102 through a back-end of line (BEOL) process. In the present embodiments, the integrated circuit device 100A includes an isolation layer 121 between the substrate 102 and the TFT-based interconnect structure 122, an isolation layer 123 between the TFT-based interconnect structures 122 and 124, and an isolation layer 125 between the TFT-based interconnect structures 124 and 126. The isolation layers 121, 123, and 125 may be made of suitable materials for providing chemical and electrical isolations. In some embodiments, the isolation layers 121, 123, and 125 may include ceramics. For example, the isolation layers 121, 123, and 125 may include metal-containing compound materials, such as Al₂O₃, Zr₂O₃, TiO₂, other metal oxides, the like, or the combination thereof. These materials may have a lower water vapor transmission rate (WVTR) than SiNₓ, thereby achieving chemical isolation. For example, the isolation layers 121, 123, and 125 may serve as a hydrogen diffusion barrier. These materials may also have small leakage current due to their large band gap, thereby achieving electrical isolation. Conductive vias V1-V3 may extend through the isolation layers 121, 123, and 125, respectively, for establishing electrical connections among the substrate 102 and the TFT-based interconnect structures 122, 124, and 126. The conductive vias V1-V3 may include one or more barrier/adhesion layers MB and one or more conductive materials FM surrounded by the barrier/adhesion layer(s) MB.

FIG. 1B is an exemplary cross-sectional view showing the configuration of the integrated circuit device 100A of FIG. 1A. One or more active and/or passive devices 104 are formed over the substrate 102, a FEOL interlayer dielectric (ILD) layer 110 is formed overlying the active and/or passive devices 104, and contact plugs 112 are formed in the ILD layer 110 to connect the active and/or passive devices 104. The interconnect structure 120 electrically interconnects the one or more active and/or passive devices 104 to form functional electrical circuits. In the present embodiments, each of the TFT-based interconnect structures 122, 124, and 126 of the interconnect structure 120 includes one or more metallization layers. For example, each of the TFT-based interconnect structures 122, 124, and 126 may include one or more dielectric layers DI and a metallization pattern MP in the dielectric layers DI. In some embodiments, the dielectric layers DI may include undoped silicate glass (USG), low-k dielectric material, extreme low-k dielectric material, SiO₂, or other suitable materials. The dielectric layers DI may be referred to as inter-metal dielectric (IMD) or interlayer dielectric (ILD). The metallization pattern MP may include one or more horizontal interconnects, such as conductive lines CL, respectively extending horizontally or laterally in the dielectric layers DI and vertical interconnects, such as conductive vias CV, respectively extending vertically in the dielectric layers DI. The interconnect of the metallization pattern MP (e.g., the conductive lines CL and conductive vias CV) may be made of suitable conductive materials, such as Cu. In some embodiments, portions of the conductive vias CV of the metallization pattern MP may extend through the isolation layers 121, 123, and 125, and serve as the conductive vias V1-V3 in the isolation layers 121, 123, and 125 in FIG. 1A.

The one or more active and/or passive devices 104 are illustrated as a single transistor in FIG. 1B. For example, the device 104 may include a gate structure 104_{G} and source/drain regions 104_{SD} over regions surrounded by shallow trench isolation (STI) regions 105. The gate structure 104_{G} may include a gate dielectric 104_{GD} and a gate electrode 104_{GM} over the gate dielectric 104_{GD}. The spacers 104_{SP} may be formed on opposite sides of the gate structure 104_{G}. In some embodiments, the source and drain regions 104_{SD} may be doped regions formed in the substrate 102. In some alternative embodiments, the source and drain regions 104_{SD} may be epitaxial structures formed over the substrate 102. The one or more active and/or passive devices 104 may include various N-type metal-oxide semiconductor (NMOS) and/or P-type metal-oxide semiconductor (PMOS) devices, such as transistors, capacitors, resistors, diodes, photo-diodes, fuses, and the like. It is appreciated that the above examples are provided for the purpose of illustration only and are not meant to limit the present disclosure in any manner. Other circuitry may be also formed as appropriate for a given application.

Contact plugs 112 electrically couple the overlying interconnect structure 120 to the underlying devices 104. In the example illustrated in FIG. 1B, the contact plugs 112 make electrical connections to the gate structure 104G and the source/drain regions 104_{SD} of FinFET device 104.

In the present embodiments, the TFT-based interconnect structures 122, 124, and 126 may respectively include devices 122T, 124T, and 126T. The devices 122T, 124T, and 126T include thin film transistors (TFTs). In some embodiments, the devices may further include non-volatile memory devices (e.g., spin-transfer-torque magnetoresistive random access memory (STT-MRAM)), volatile memory devices (e.g., embedded dynamic random access memory (eDRAM)), the like, or the combination thereof. In some embodiments of the present disclosure, the devices 122T, 124T, and 126T are illustrated and referred to as thin film transistors (TFTs), each may include a semiconductor layer SL and a gate structure GS over the semiconductor layer SL. TFTs are a kind of field-effect transistors (FETs) in which the channel material (e.g., the semiconductor layer SL) is a deposited thin film rather than a monocrystalline material. The channel material (e.g., the semiconductor layer SL) of the TFTs can be made using a wide variety of semiconductor materials, such as silicon, germanium, silicon-germanium, 2D materials (MoS₂, graphene, etc.), poly-Si based TFT, as well as various oxide semiconductors (a.k.a. semiconducting oxides) including metal oxides like indium gallium zinc oxide (IGZO). The gate structure GS may include a gate dielectric GI over the semiconductor layer SL and a gate electrode GE over the gate dielectric GI. The semiconductor layer SL may include a channel region CR below the gate structure GS and source/drain regions SDR on opposite sides of the channel region CR. The metallization pattern MP (e.g., the conductive lines CL and conductive vias CV) may establish electrical connections to the semiconductor device 104 and the TFTs 122T, 124T, and 126T.

In absence of the isolation layers 121, 123, and 125, a silicon oxide layer and/or a silicon nitride layer may be used intervening between the ILD layer 110 and the TFT-based interconnect structure 122, and silicon oxide layers and/or silicon nitride layers may be used intervening between two adjacent TFT-based interconnect structures 122, 124, and 126. Silicon nitride may be formed using a hydrogen-containing precursor (e.g., silane (SiH₄)), for example, through a plasma-enhance chemical vapor deposition (PECVD) process, and thus acting as a large hydrogen source. Silicon oxide has a large diffusion length allows hydrogen diffusion. Therefore, silicon oxide layers and/or silicon nitride layers may allow hydrogen to diffuse from the dielectric layers DI (SiOₓ) to the channel region (e.g. IGZO) of the TFTs. The hydrogen diffusion may reduce effective channel length, and cause variation in the threshold voltage (V_{T}) of the TFTs. For example, the threshold voltages (V_{T}) of the TFTs of the integrated circuit device may shift negatively or positively, causing threshold voltage instability of the integrated circuit device. This may enhance short channel effect, and lower the scalability.

In some embodiments of the present disclosure, the isolation layers 121, 123, and 125 are formed by a suitable deposition process using less or no hydrogen-containing precursor, such that the formed isolation layers 121, 123, and 125 have a lower hydrogen concentration than that of the silicon nitride layer. For example, the isolation layers 121, 123, and 125 may be formed by a physical vapor deposition process (PVD) (e.g., radio frequency sputter (RF sputter) deposition), an atomic layer deposition (ALD) process, a PECVD process, other suitable deposition process, or the combination thereof. Thus, the isolation layers 121, 123, and 125 may not act as a large hydrogen source as the silicon nitride layer does. In some examples, the isolation layers 121, 123, and 125 formed by ALD may have a hydrogen concentration in a range from about 1% to about 2%, and the silicon nitride layer formed by PECVD may have a hydrogen concentration in a range from about 10% to about 20%. In some examples, the isolation layers 121, 123, and 125 formed by PVD process (e.g., sputter deposition) may have a hydrogen concentration less than 1%. Through the configuration, the hydrogen diffusion to the channel region CR of the TFTs 122T-126T is reduced, which in turn will enhance the stability of the threshold voltages (V_{T}) of the stacked TFTs.

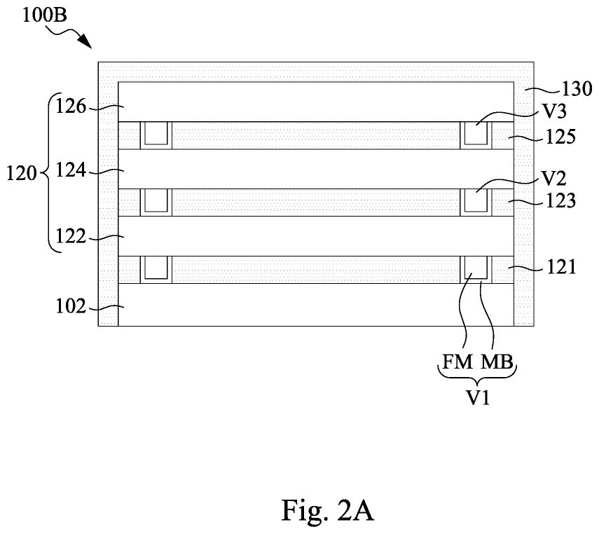

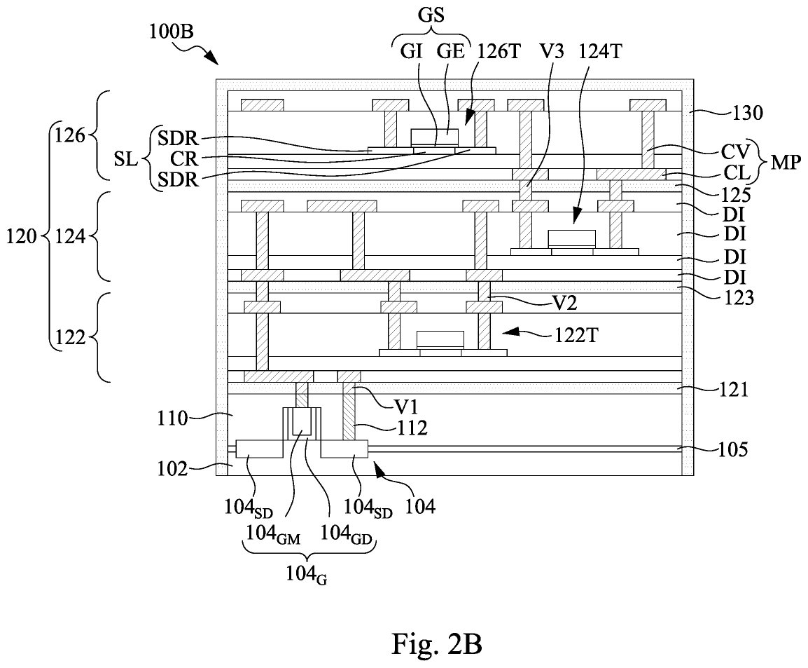

FIG. 2A is a schematic cross-sectional view of an integrated circuit device 100B according to some embodiments of the present disclosure. FIG. 2B is an exemplary cross-sectional view showing the configuration of the integrated circuit device 100B of FIG. 2A. The details of the present embodiments are similar to those of FIGS. 1A and 1B, except that the integrated circuit device 100B further includes an encapsulation layer 130 encapsulating the substrate 102 and the BEOL interconnect structure 120, thereby mitigating the moisture diffusion from the environment (side isolation) into the TFTs 122T, 124T, and 126T.

The encapsulation layer 130 may be made of suitable materials for providing chemical and electrical isolations. In some embodiments, the encapsulation layer 130 may include ceramics. For example, the encapsulation layer 130 may be made of metal-containing compound materials, such as Al₂O₃, Zr₂O₃, TiO₂, the like, or the combination thereof. These materials may have a lower WVTR than SiNX, thereby achieving chemical isolation. For example, the encapsulation layer 130 may serve as a hydrogen diffusion barrier. These materials may also have small leakage current due to their large band gap, thereby achieving electrical isolation. In some embodiments, the isolation layers 121, 123, and 125 and the encapsulation layer 130 may include the same material, such as Al₂O₃. In some other embodiments, at least two of the isolation layers 121, 123, and 125 and the encapsulation layer 130 may include different materials. In some alternative embodiments, while the encapsulation layer 130 encapsulates the substrate 102 and the BEOL interconnect structure 120, some or all of the isolation layers 121, 123, and 125 may be omitted.

In some embodiments of the present disclosure, the encapsulation layer 130 is formed by a suitable deposition process using less or no hydrogen-containing precursor, such that the encapsulation layer 130 have a lower hydrogen concentration than that of the silicon nitride layer. For example, the encapsulation layer 130 may be formed by a PVD process (e.g., RF sputter deposition), an ALD process, a PECVD process, other suitable deposition process, or the combination thereof. Thus, the encapsulation layer 130 may not act as a large hydrogen source as the silicon nitride layer does. In some examples, the encapsulation layer 130 formed by ALD process may have a hydrogen concentration in a range from about 1% to about 2%, and the silicon nitride layer formed by PECVD may have a hydrogen concentration in a range from about 10% to about 20%. In some examples, the encapsulation layer 130 formed by the sputter deposition may have a hydrogen concentration less than 1%. Through the configuration, the hydrogen diffusion to the channel region CR of the TFTs 122T-126T is reduced, which in turn will enhance the stability of the threshold voltages (V_{T}) of the stacked TFTs.

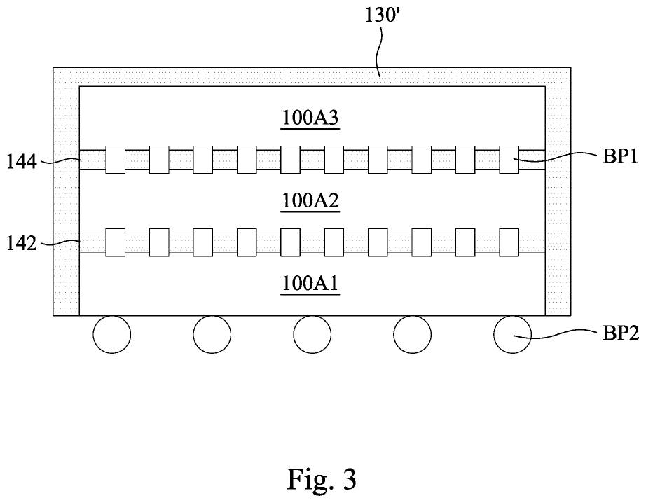

FIG. 3 is a schematic cross-sectional view of an integrated circuit device 100C according to some embodiments of the present disclosure. The details of the present embodiments are similar to those of FIGS. 1A and 1B, except that the integrated circuit device 100C has plural chips 100A1-100A3 stacked vertically as chiplet stacking, isolation layers 142 and 144 are disposed between two adjacent two of the chips 100A1-100A3, and an encapsulation layer 130′ is formed to encapsulate the chips 100A1-100A3. The isolation layers 142 and 144 can mitigate the moisture diffusion between chips, and the encapsulation layer 130′ can mitigate the moisture diffusion from the environment (side isolation) into the TFTs 122T, 124T, and 126T in the chips 100A1-100A3.

The integrated circuit device 100C may include chips 100A1-100A3. Each of the chips 100A1-100A3 may include a substrate and an interconnect structure over the substrate as the configuration of the integrated circuit device 100A. The chips 100A1-100A3 may have different functions, such as input/output (I/O) interface, memory, processor, the like, or the combination thereof. For example, in some embodiments, the chips 100A1-100A3 are respectively an I/O chip, a microprocessor core chip, and a memory chip.

The isolation layers 142 and 144 and the encapsulation layer 130′ may be made of suitable materials for providing chemical and electrical isolations. Details of the isolation layers 142 and 144 may be similar to that of the isolation layers 121, 123, and 125 (referring to FIGS. 1A-2B), and therefore not repeated herein. In some embodiments, as the configuration of the device 100A shown in FIG. 1A, some or all the chips 100A1-100A3 may include the isolation layers 121, 123, and 125 disposed between adjacent two interconnect structure/layers thereof.

In some embodiments, conductive connectors BP1 are disposed between two adjacent chips of the chips 100A1-100A3, extending through the isolation layers 142 and 144, so as to provide electrical connection between the two adjacent chips. The conductive connectors BP may include a conductive material such as solder, copper, aluminum, gold, nickel, silver, palladium, tin, the like, or a combination thereof. In some embodiments, solder balls BP2 may be disposed on a side of the chip 100A2 opposite to the chip 100A1. The solder balls BP2 can be formed through evaporation, electroplating, printing, solder transfer, ball placement, or the like.

The encapsulation layer 130′ may be formed around the chips 100A1-100A3. The encapsulation layer 130′ may be made of suitable materials for providing chemical and electrical isolations. Details of the isolation layers 142 and 144 may be similar to that of the isolation layers 121, 123, and 125 (referring to FIGS. 1A-2B), and therefore not repeated herein. In some embodiments, the isolation layers 121, 123, and 125 and the encapsulation layer 130′ may include the same material. In some other embodiments, at least two of the isolation layers 121, 123, and 125 and the encapsulation layer 130′ may include different materials. Other details of the present embodiments are similar to those described above, and thereto not repeated herein.

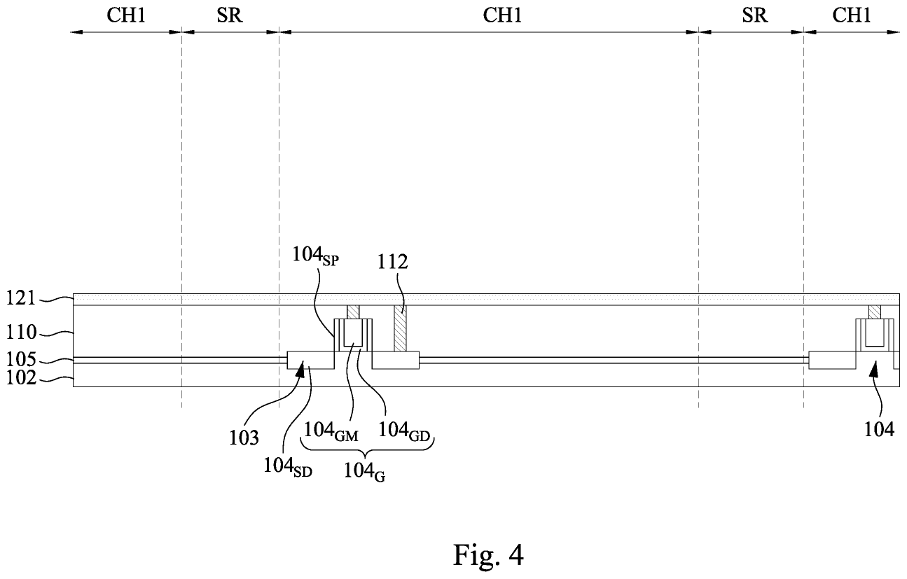

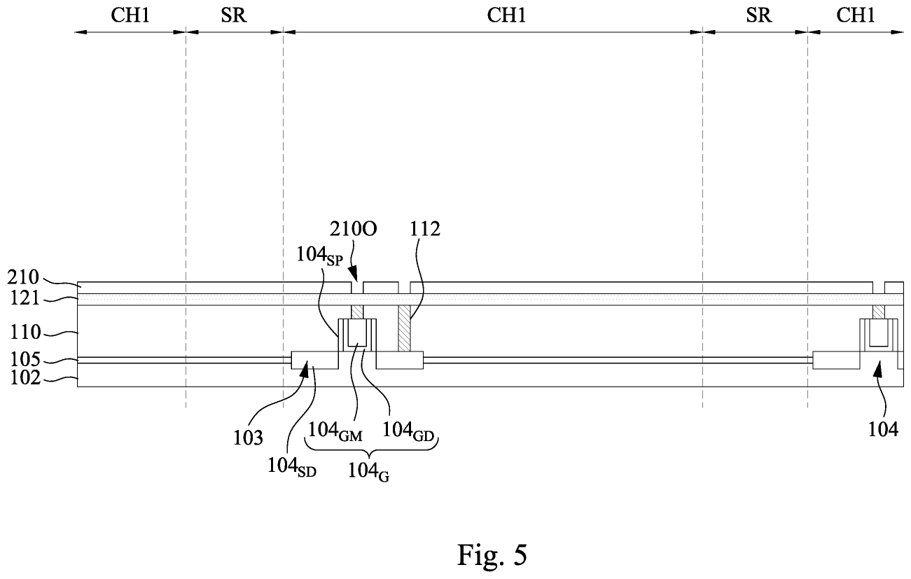

FIGS. 4-15 illustrate a method for fabricating an integrated circuit device at various intermediate stages of manufacture according to some embodiments of the present disclosure. It is understood that additional operations may be provided before, during, and after the operations shown by FIGS. 4-15, and some of the operations described below can be replaced or eliminated for additional embodiments of the method. The order of the operations/processes may be interchangeable.

Reference is made to FIG. 4. In some embodiments, a substrate 102 is provided. The substrate 102 may comprise a substantially monocrystalline material, for example, bulk silicon. In some other embodiments, the substrate 102 may include another elementary semiconductor, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In some embodiments, the substrate 102 may comprise an active layer of a semiconductor-on-insulator (SOI) substrate. An SOI substrate comprises a layer of a semiconductor material, such as silicon, formed on an insulator layer. The insulator layer may be, for example, a buried oxide (BOX) layer or a silicon oxide layer. The insulator layer is provided on a substrate, such as a silicon or glass substrate. Other substrates, such as multi-layered or gradient substrates, may also be used. For clear illustration, the substrate 102 is illustrated as including plural chip regions CH1 and a dicing path region SR surrounding the chip regions CH1. The dicing path region SR may comprise a scribe line region or a scribe region in some embodiments.

In some embodiments, one or more active and/or passive devices 104 are formed on the chip regions CH1 of the substrate 102. In the depicted embodiments, the devices 104 are fin field-effect transistors (FinFET) that are three-dimensional MOSFET structure formed in fin-like strips of semiconductor protrusions referred to as fins 103. The cross-section shown in FIG. 4 is taken along a longitudinal axis of the fin 103 in a direction parallel to the direction of the current flow between the source/drain regions 104_{SD}. The fin 103 may be formed by patterning the substrate 102 using photolithography and etching techniques. For example, a spacer image transfer (SIT) patterning technique may be used. In this method a sacrificial layer is formed over a substrate and patterned to form mandrels using suitable photolithography and etch processes. Spacers are formed alongside the mandrels using a self-aligned process. The sacrificial layer is then removed by an appropriate selective etch process. Each remaining spacer may then be used as a hard mask to pattern the respective fin 103 by etching a trench into the substrate 102 using, for example, reactive ion etching (RIE). FIG. 4 illustrates a single fin 103, although the substrate 102 may comprise any number of fins. In some other embodiments, the devices 104 can be planar transistors or gate-all-around (GAA) transistors. The GAA transistor may be fabricated by channel stacking techniques, and stacked nanosheet (NS) can enhance the Iₒₙ at fixed footprint.

STI regions 105 are formed on opposing sidewalls of the fin 103 are illustrated in FIG. 4. STI regions 105 may be formed by depositing one or more dielectric materials (e.g., silicon oxide) to completely fill the trenches around the fins and then recessing the top surface of the dielectric materials. The dielectric materials of the STI regions 105 may be deposited using a high density plasma chemical vapor deposition (HDP-CVD), low-pressure CVD (LPCVD), sub-atmospheric CVD (SACVD), a flowable CVD (FCVD), spin-on, and/or the like, or a combination thereof. After the deposition, an anneal process or a curing process may be performed. In some cases, the STI regions 105 may include a liner such as, for example, a thermal oxide liner grown by oxidizing the silicon surface. The recess process may use, for example, a planarization process (e.g., a chemical mechanical polish (CMP)) followed by a selective etch process (e.g., a wet etch, or dry etch, or a combination thereof) that may recess the top surface of the dielectric materials in the STI region 105 such that an upper portion of fins 103 protrudes from surrounding insulating STI regions 105. In some cases, the patterned hard mask used to form the fins 103 may also be removed by the planarization process.

In some embodiments, a gate structure 104_{G} of the FinFET device 104 illustrated in FIG. 4 is a high-k, metal gate (HKMG) gate structure that may be formed using a gate-last process flow. In a gate-last process flow, a sacrificial dummy gate structure (not shown) is formed after forming the STI regions 105. The dummy gate structure may comprise a dummy gate dielectric, a dummy gate electrode, and a hard mask. First a dummy gate dielectric material (e.g., silicon oxide, silicon nitride, or the like) may be deposited. Next a dummy gate material (e.g., amorphous silicon, polycrystalline silicon, or the like) may be deposited over the dummy gate dielectric and then planarized (e.g., by CMP). A hard mask layer (e.g., silicon nitride, silicon carbide, or the like) may be formed over the dummy gate material. The dummy gate structure is then formed by patterning the hard mask and transferring that pattern to the dummy gate dielectric and dummy gate material using suitable photolithography and etching techniques. The dummy gate structure may extend along multiple sides of the protruding fins and extend between the fins over the surface of the STI regions 105. As described in greater detail below, the dummy gate structure may be replaced by the HKMG gate structure 104_{G} as illustrated in FIG. 4. The materials used to form the dummy gate structure and hard mask may be deposited using any suitable method such as CVD, plasma-enhanced CVD (PECVD), atomic layer deposition (ALD), plasma-enhanced ALD (PEALD) or the like, or by thermal oxidation of the semiconductor surface, or combinations thereof.

In FIG. 4, source/drain regions 104_{SD} and spacers 104_{SP} of the transistor device 104 are formed, for example, self-aligned to the dummy gate structures. Spacers 104_{SP} may be formed by deposition and anisotropic etch of a spacer dielectric layer performed after the dummy gate patterning is complete. The spacer dielectric layer may include one or more dielectrics, such as silicon oxide, silicon nitride, silicon oxynitride, silicon carbide, silicon carbonitride, the like, or a combination thereof. The anisotropic etch process removes the spacer dielectric layer from over the top of the dummy gate structures leaving the spacers 104_{SP} along the sidewalls of the dummy gate structures extending laterally onto a portion of the surface of the fin 103.

Source/drain regions 104_{SD} are semiconductor regions in direct contact with the semiconductor fin 103. In some embodiments, the source/drain regions 104_{SD} may comprise heavily-doped regions and relatively lightly-doped drain extensions, or LDD regions. Generally, the heavily-doped regions are spaced away from the dummy gate structures using the spacers 104_{SP}, whereas the LDD regions may be formed prior to forming spacers 104_{SP} and, hence, extend under the spacers 104_{SP} and, in some embodiments, extend further into a portion of the semiconductor fin 103 below the dummy gate structure. The LDD regions may be formed, for example, by implanting dopants (e.g., As, P, B, In, or the like) using an ion implantation process.

The source/drain regions 104_{SP} may comprise an epitaxially grown region. For example, after forming the LDD regions, the spacers 104_{SP} may be formed and, subsequently, the heavily-doped source and drain regions may be formed self-aligned to the spacers 104_{SP} by first etching the fins to form recesses, and then depositing a crystalline semiconductor material in the recess by a selective epitaxial growth (SEG) process that may fill the recess and may extend further beyond the original surface of the fin 103 to form raised source/drain epitaxy structures. The crystalline semiconductor material may be elemental (e.g., Si, or Ge, or the like), or an alloy (e.g., Si₁₋ₓCₓ, or Si₁₋ₓGeₓ, or the like). The SEG process may use any suitable epitaxial growth method, such as e.g., vapor/solid/liquid phase epitaxy (VPE, SPE, LPE), or metal-organic CVD (MOCVD), or molecular beam epitaxy (MBE), or the like. A high dose (e.g., from about 10¹⁴ cm⁻² to 10¹⁶ cm⁻²) of dopants may be introduced into the heavily-doped source and drain regions 104_{SD} either in situ during SEG, or by an ion implantation process performed after the SEG, or by a combination thereof.

Once the source/drain regions 104_{SD} are formed, a first ILD layer (e.g., lower portion of the ILD layer 110) is deposited over the source/drain regions 104_{SD}. In some embodiments, a contact etch stop layer (CESL) (not shown) of a suitable dielectric (e.g., silicon nitride, silicon carbide, or the like, or a combination thereof) may be deposited prior to depositing the ILD material. A planarization process (e.g., CMP) may be performed to remove excess ILD material and any remaining hard mask material from over the dummy gates to form a top surface wherein the top surface of the dummy gate material is exposed and may be substantially coplanar with the top surface of the first ILD layer. The HKMG gate structures 104_{G}, illustrated in FIG. 4, may then be formed by first removing the dummy gate structures using one or more etching techniques, thereby creating recesses between respective spacers 104_{SP}. Next, a replacement gate dielectric layer 104_{GD} comprising one more dielectrics, followed by a replacement gate metal layer 104_{GM} comprising one or more metals, are deposited to completely fill the recesses. Excess portions of the gate dielectric layer 104_{GD} and the gate metal layer 1040_{GM} may be removed from over the top surface of first ILD using, for example, a CMP process. The resulting structure, as illustrated in FIG. 4, may include remaining portions of the gate dielectric layer 104_{GD} and the gate metal layer 104_{GM} inlaid between respective spacers 104_{SP}.

The gate dielectric layer 104_{GD} includes, for example, a high-k dielectric material such as oxides and/or silicates of metals (e.g., oxides and/or silicates of Hf, Al, Zr, La, Mg, Ba, Ti, and other metals), silicon nitride, silicon oxide, and the like, or combinations thereof, or multilayers thereof. In some embodiments, the gate metal layer 104_{GM} may be a multilayered metal gate stack comprising a barrier layer, a work function layer, and a gate-fill layer formed successively on top of gate dielectric layer 104_{GD}. Example materials for a barrier layer include TiN, TaN, Ti, Ta, or the like, or a multilayered combination thereof. A work function layer may include TiN, TaN, Ru, Mo, Al, for a p-type FET, and Ti, Ag, TaAl, TaAlC, TiAlN, TaC, TaCN, TaSiN, Mn, Zr, for an n-type FET. Other suitable work function materials, or combinations, or multilayers thereof may be used. The gate-fill layer which fills the remainder of the recess may comprise metals such as Cu, Al, W, Co, Ru, or the like, or combinations thereof, or multi-layers thereof. The materials used in forming the gate structure may be deposited by any suitable method, e.g., CVD, PECVD, PVD, ALD, PEALD, electrochemical plating (ECP), electroless plating and/or the like.

After forming the HKMG gate structure 104_{G}, a second ILD layer is deposited over the first ILD layer, and these ILD layers are in combination referred to as the ILD layer 110, as illustrated in FIG. 4. In some embodiments, the insulating materials to form the first ILD layer and the second ILD layer may comprise silicon oxide, phosphosilicate glass (PSG), borosilicate glass (BSG), boron-doped phosphosilicate glass (BPSG), undoped silicate glass (USG), a low dielectric constant (low-k) dielectric such as, fluorosilicate glass (FSG), silicon oxycarbide (SiOCH), carbon-doped oxide (CDO), flowable oxide, or porous oxides (e.g., xerogels/aerogels), or the like, or a combination thereof. The dielectric materials used to form the first ILD layer and the second ILD layer may be deposited using any suitable method, such as CVD, PVD, ALD, PEALD, PECVD, SACVD, FCVD, spin-on, and/or the like, or a combination thereof.

The contact plugs 112 may be formed in the ILD layer 110 using photolithography, etching and deposition techniques. For example, a patterned mask may be formed over the ILD layer 110 and used to etch openings that extend through the ILD layer 110 to expose the gate structure 104_{G} as well as the source/drain regions 104_{SD}. Thereafter, conductive liner may be formed in the openings in the ILD layer 110. Subsequently, the openings are filled with a conductive fill material. The liner comprises barrier metals used to reduce out-diffusion of conductive materials from the contact plugs 112 into the surrounding dielectric materials. In some embodiments, the liner may comprise two barrier metal layers. The first barrier metal comes in contact with the semiconductor material in the source/drain regions 104_{SD} and may be subsequently chemically reacted with the heavily-doped semiconductor in the source/drain regions 104_{SD} to form a low resistance ohmic contact, after which the unreacted metal may be removed. For example, if the heavily-doped semiconductor in the source/drain regions 104_{SD} is silicon or silicon-germanium alloy semiconductor, then the first barrier metal may comprise Ti, Ni, Pt, Co, other suitable metals, or their alloys, and may form silicide with the source/drain regions 104_{SD}. The second barrier metal layer of the conductive liner may additionally include other metals (e.g., TiN, TaN, Ta, or other suitable metals, or their alloys). A conductive fill material (e.g., W, Al, Cu, Ru, Ni, Co, alloys of these, combinations thereof, and the like) may be deposited over the conductive liner layer to fill the contact openings, using any acceptable deposition technique (e.g., CVD, ALD, PEALD, PECVD, PVD, ECP, electroless plating, or the like, or any combination thereof). Next, a planarization process (e.g., CMP) may be used to remove excess portions of all the conductive materials from over the surface of the ILD 110. The resulting conductive plugs extend into the ILD layer 110 and constitute contact plugs 112 making physical and electrical connections to the electrodes of electronic devices, such as the tri-gate FinFET device 104 illustrated in FIG. 4.

An isolation layer 121 is deposited over the ILD layer 110. The isolation layer 121 may include suitable materials for providing chemical and electrical isolations. In some embodiments, the isolation layer 121 may include ceramics. For example, the isolation layer 121 may include metal-containing compound materials, such as Al₂O₃, Zr₂O₃, TiO₂, the like, or the combination thereof. After the formation of the isolation layer 121, a CMP process may be optionally performed to planarize a top surface of the isolation layer 121.

In the present embodiments, as aforementioned, the isolation layer 121 may be formed by a suitable deposition process using less or no hydrogen-containing precursor than the deposition process of silicon nitride, thereby having a lower hydrogen concentration than that of the silicon nitride layer. For example, the isolation layer 121 may be formed by PVD process (e.g., RF sputter), an atomic layer deposition (ALD) process, a PECVD process, other suitable deposition process, or the combination thereof. In some embodiments, the PVD process (e.g., sputter) may be performed without using a hydrogen-containing precursor. Thus, the isolation layer 121 formed by the sputtering may have a hydrogen concentration less than 1%. In some embodiments, the ALD process may be performed using a hydrogen-containing precursor (e.g., trimethylaluminum (TMA)) providing a less hydrogen content than that of the hydrogen-containing precursor (e.g., silane) used in the formation of silicon nitride. Thus, the isolation layer 121 formed by ALD may have a hydrogen concentration in a range from about 1% to about 2%. The isolation layer 121 may be a single layer, a multilayer stack, or a composite structure. For the isolation layer 121 having the composite structure, a co-sputtering process where two or more target (or source) materials are sputtered is performed to produce thin films that are combinatorial such as metal alloys or non-metallic compositions such as ceramics.

In some embodiments, the isolation layer 121 may have a thickness in a range from about 1 nanometer to about 1000 nanometers. If the thickness of the isolation layer 121 is less than about 1 nanometer, the isolation layer 121 may have poor film uniformity, and devices 104 in the FEOL ILD 110 may be damaged due to the etch process in the formation of the conductive vias. If the thickness of the isolation layer 121 is greater than about 1000 nanometers, it becomes difficult to form conductive vias in the isolation layer 121. The deposition temperature of the isolation layer 121 may be in a range from about 100 K to about 1000 K. If the deposition temperature of the isolation layer 121 is less than about 100K or greater than about 1000 K, it becomes difficult to form the isolation layer 121.

In some embodiments, the ALD Al₂0₃ has a lower WVTR and a thinner film thickness than that of the RF sputtered Al₂O₃. For example, the ALD Al₂O₃ may have a WVTR in a range from about 10⁻⁵ g m⁻² day⁻¹ to about 10⁻⁷ g m⁻² day⁻¹ and a film thickness in a range from about 1 nanometers to about 20 nanometers. The RF sputtered Al₂O₃ may have a WVTR in a range from about 0.1 g m⁻² day⁻¹ to about 2 g m⁻² day⁻¹ and a film thickness in a range from about 20 nanometers to about 1 micrometer. Since the ALD process may use a hydrogen-containing precursor (e.g., TMA), the ALD Al₂O₃ may have a higher hydrogen concentration than that of the RF sputtered Al₂O₃.

Depending on the device requirements, one of the ALD and PVD (e.g., sputter deposition) processes can be chosen for forming the isolation layer (e.g., Al₂O₃) with a suitable WVTR, a suitable film thickness, and a suitable hydrogen concentration.

Reference is made to FIG. 5. A photoresist mask 210 is formed over the structure of FIG. 4 and exposing parts of the isolation layer 121. The photoresist mask 210 may include a photosensitive material. The photoresist mask 210 may be formed by suitable photolithography process, and have openings (or trenches) 210O therein. The photolithography process may include coating a photoresist layer, exposing the photoresist to a pattern, performing post-exposure bake processes, and developing the resist to form a patterned mask including the resist. In some alternative embodiments, the photoresist mask may be a tri-layer photoresist. For example, the photoresist mask 210 includes a bottom layer, a middle layer over the bottom layer, and a photoresist layer over the middle layer. The bottom layer may include organic or inorganic material. The middle layer may include silicon nitride, silicon oxynitride, SiOC, or the like. The photoresist layer may include a photosensitive material.

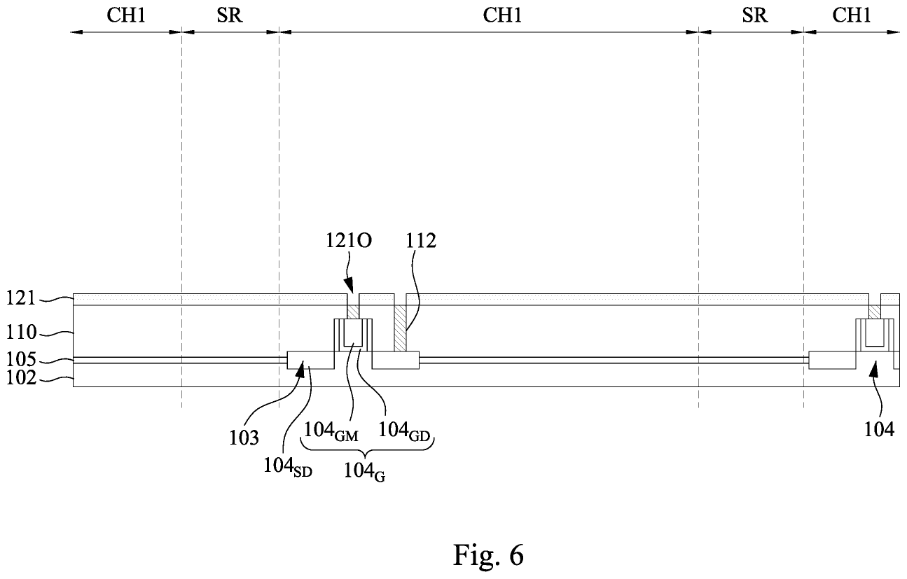

Reference is made to FIG. 6. The isolation layer 121 is patterned to have openings 1210 exposing the underlying conductive features, such as contact plugs 112. In some embodiments, the isolation layer 121 is etched through the openings 210O of the photoresist mask 210 (referring to FIG. 5), thereby forming the openings 121O therein. The patterning may include one or more etching processes. The etching process may include a dry etch process, a wet etch process, or the combination thereof. The photoresist mask 210 may serve as an etch mask during the etching process. After the etching process, the photoresist mask 210 may be stripped off by suitable ashing process.

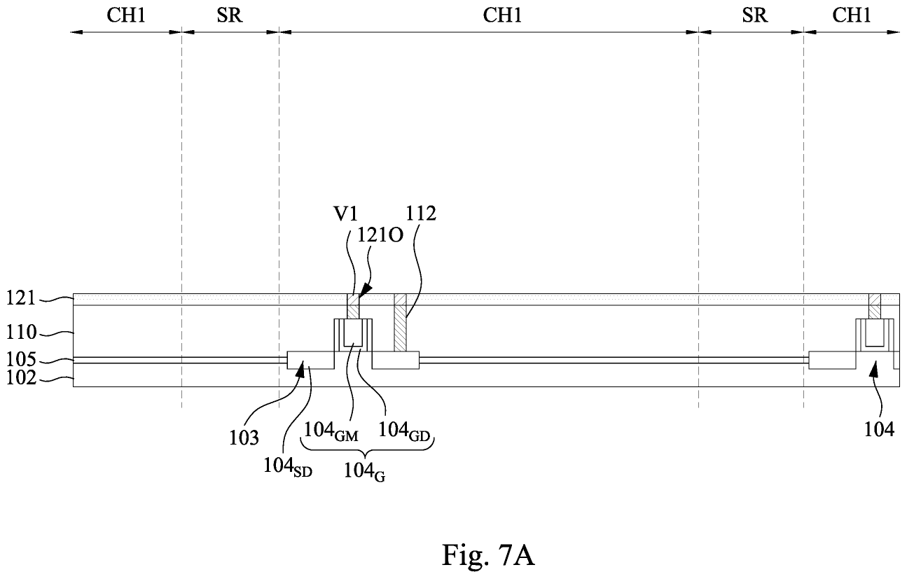

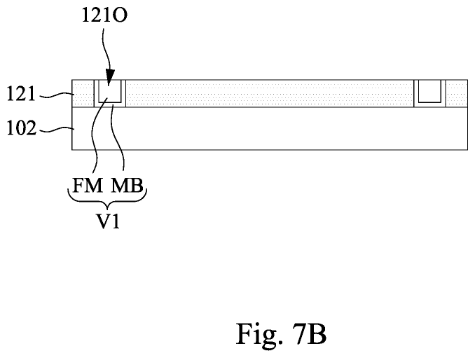

Reference is made to FIG. 7A. Conductive vias V1 are formed in the openings 121O of the isolation layer 121 to connect the contact plugs 112. FIG. 7B is a schematic cross-sectional view showing the configuration of the conductive vias V1 in the openings 121O of the isolation layer 121. Reference is made to FIGS. 7A and 7B. Formation of the conductive vias V1 may include filling the openings 121O with one or more conductive materials FM, followed by a CMP process to remove excess materials of the conductive materials FM. In some embodiments, the one or more conductive materials FM may include copper (Cu), tungsten (W), aluminum (Al), titanium (Ti), titanium nitride (TiN), tantalum nitride (TaN), the like, or the combination thereof. In some embodiments, one or more barrier/adhesion layers MB may be deposited into the openings 1210 prior to depositing the one or more conductive materials FM. The one or more barrier/adhesion layers MB may comprise titanium, titanium nitride, tantalum, tantalum nitride, the like, or the combination thereof, and may be formed using PVD, CVD, ALD, or the like.

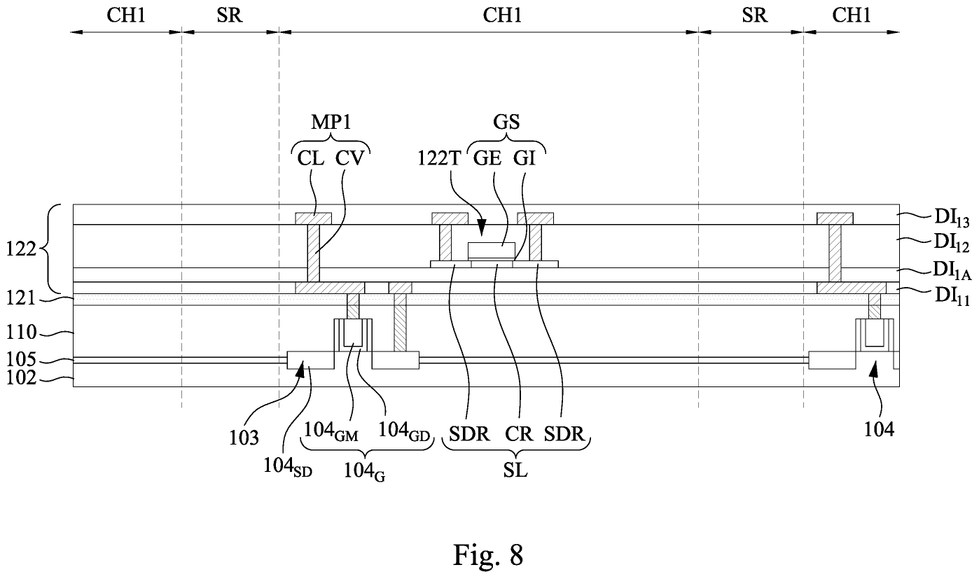

Reference is made to FIG. 8. A TFT-based interconnect structure 122 may be formed over the isolation layer 121. The TFT-based interconnect structure 122 may include multiple interconnect levels formed in the respective dielectric layers DI₁₁ to DI₁₃ using any suitable method, such as a single damascene process, a dual damascene process, or the like. The interconnect levels may include one or more horizontal interconnects, such as conductive lines CL, respectively extending horizontally or laterally in the dielectric layers DI₁₁ and DI₁₃ and vertical interconnects, such as conductive vias CV, extending vertically in the dielectric layer DI₁₂. A combination of the conductive lines CL and the conductive vias CV in these dielectric layers DI₁₁ to DI₁₃ can be referred to as the metallization pattern MPI.

In some embodiments, the dielectric layers DI₁₁ to DI₁₃ may include low-k dielectric materials having k values, for example, lower than about 4.0 or even 2.0 disposed between such conductive features. In some embodiments, the dielectric layers DI₁₁ to DI₁₃ may be made of, for example, phosphosilicate glass (PSG), borophosphosilicate glass (BPSG), fluorosilicate glass (FSG), SiOxCy, Spin-On-Glass, Spin-On-Polymers, silicon oxide, silicon oxynitride, combinations thereof, or the like, formed by any suitable method, such as spin-on coating, chemical vapor deposition (CVD), plasma-enhanced CVD (PECVD), or the like.

The conductive lines CL and the conductive vias CV may comprise conductive materials such as copper, aluminum, tungsten, combinations thereof, or the like. In some embodiments, the conductive lines CL and the conductive vias CV may further comprise one or more barrier/adhesion layers (not shown) to protect the respective dielectric layers DI₁₁ to DI₁₃ from metal diffusion (e.g., copper diffusion) and metallic poisoning. The one or more barrier/adhesion layers may comprise titanium, titanium nitride, tantalum, tantalum nitride, or the like, and may be formed using PVD, CVD, ALD, or the like.

In some embodiments, the TFT-based interconnect structure 122 may further include a TFT 122T surrounded by the dielectric layer DI₁₂. An additional dielectric layer DI_{1A} is formed over a metallization layer of TFT-based interconnect structure 122 (e.g., the dielectric layer DI₁₁ and the conductive line CL in the dielectric layer DI₁₁). The dielectric layer DI_{1A} serves as a base dielectric layer supporting the TFT 122T (e.g., the semiconductor layer SL). The dielectric layer DI_{1A} may include low-k dielectric materials. In some embodiments, the dielectric layer DI_{1A} may be made of, for example, PSG, BPSG, FSG, SiOₓC_{y}, Spin-On-Glass, Spin-On-Polymers, silicon oxide, silicon oxynitride, combinations thereof, or the like, formed by any suitable method, such as spin-on coating, CVD, PECVD, or the like. As the dielectric layer DI_{1A} plays a different role than the dielectric layers DI₁₁ and DI₁₃, the dielectric layer DI_{1A} may have a different thickness and/or material than that of the dielectric layers DI₁₁ and DI₁₃. For example, the dielectric layer DI_{1A} may be thinner or thicker than one or more of the dielectric layers DI₁₁ and DI₁₃. Alternatively, the dielectric layer DI_{1A} may have a same thickness and/or material as one or more of the dielectric layers DI₁₁ and DI₁₃.

The fabrication process of the TFT 122T may include depositing a semiconductor layer SL over the dielectric layer DI_{1A}. The semiconductor layer SL is patterned to have a suitable pattern by lithography and etching process. A gate structure GS is then formed over a portion of the semiconductor layer SL. Formation of the gate structure GS include depositing a gate dielectric layer, deposition a gate electrode layer, and patterning the gate dielectric layer and the gate electrode layer into a gate dielectric GI and a gate electrode GE. In some embodiments, the portion of the semiconductor layer SL below the gate structure GS serves as a channel region CR of the thin film transistor, and other portions of the semiconductor layer SL on opposite sides of the channel region CR may be doped and serve as source/drain regions SDR of the thin film transistor. In some embodiments of the present disclosure, the fabrication process of the TFT 122T may be performed at a temperature lower than that of the FEOL process, for example, lower than about 400° C., thereby avoiding metal diffusion of the metallization pattern and facilitating the transistor stacking. For example, a temperature of forming the semiconductor layer SL (e.g., depositing and annealing semiconductor layer SL) may be lower than a temperature of forming the epitaxial source and drain regions 104_{SD} (e.g., depositing and annealing epitaxial source and drain regions 104_{SD}) in the FEOL process.

In some embodiments, the semiconductor layer SL may be a deposited thin film rather than a monocrystalline material. For example, the semiconductor layer SL can be amorphous (i.e., having no structural order), or polycrystalline (e.g., having micro-scale to nano-scale crystal grains). In some embodiments, the semiconductor layer SL may include amorphous semiconductors (e.g., amorphous silicon) or amorphous metal-oxide semiconductors (e.g., amorphous IGZO), which has advantages of no grain boundary and high uniformity. In some embodiments, the semiconductor layer SL may include polycrystalline materials (e.g., polysilicon), which has an advantage of high mobility. In these embodiments, within the semiconductor layer SL, the channel region CR may be intrinsic or not intentionally doped, and the source/drain regions SDR may be doped to be conductive. In some other embodiments, the semiconductor layer SL may include two-dimensional material (2D material), such as transition-metal dichalcogenide (TMD)(e.g., MoS₂) or graphene, which has an advantage of ultra-high mobility. In these embodiments, the semiconductor layer SL may also be referred to as a 2D material layer.

In some embodiments, in the fabrication process of the TFT-based interconnect structure 122 shown in FIG. 8, the dielectric layers DI₁₁ is first deposited over the isolation layer 121, and conductive lines CL are formed in the dielectric layers DI₁₁ over the isolation layer 121. Subsequently, the dielectric layers DI_{1A} may be deposited over the dielectric layers DI₁₁ and the conductive lines CL, and the TFT 122T may be then formed over the dielectric layers DI_{1A}. The formed TFT 122T is over the isolation layer 121, and spaced apart from the device 104 at least in part by the isolation layer 121. A dielectric layers DI₁₂ may then be deposited over the TFT I22T, and conductive vias CV are formed in the dielectric layers DI_{1A} and DI₁₂. A dielectric layers DI₁₃ may be deposited over the dielectric layer DI₁₂, and conductive lines CL may then be formed in the dielectric layers DI₁₄. In the present embodiments, the TFT-based interconnect structure 122 is exemplarily shown by FIG. 8. In some alternative embodiments, the TFT-based interconnect structure 122 may have other configurations.

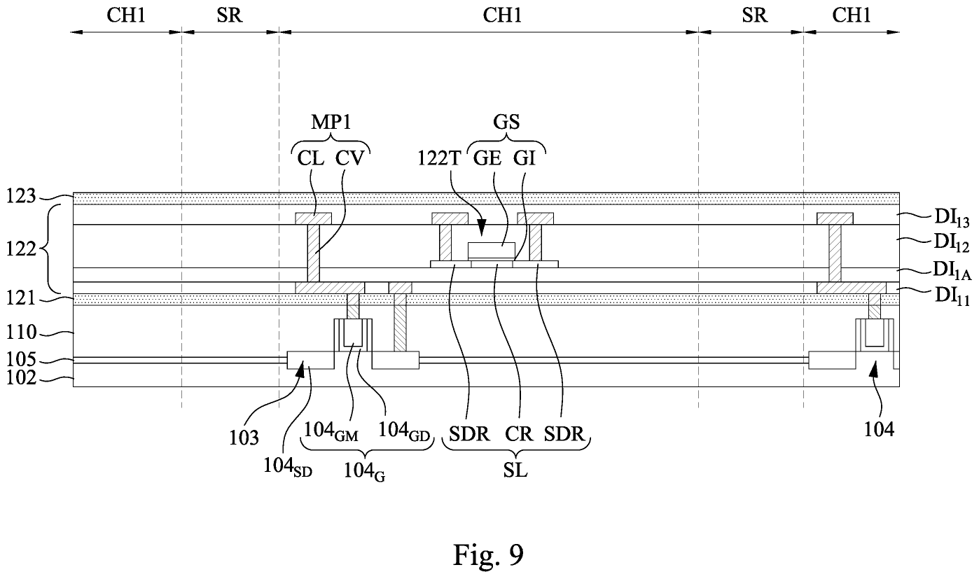

Reference is made to FIG. 9. An isolation layer 123 is deposited over the TFT-based interconnect structure 122. The isolation layer 123 may include suitable materials for providing chemical and electrical isolations. In some embodiments, the isolation layer 123 may include ceramics. For example, the isolation layer 123 may include metal-containing compound materials, such as Al₂O₃, Zr₂O₃, TiO₂, the like, or the combination thereof. In the present embodiments, as aforementioned, the isolation layer 123 may be formed by a suitable deposition process using less or no hydrogen-containing precursor than the deposition process of silicon nitride, thereby having a lower hydrogen concentration than that of the silicon nitride layer. For example, the isolation layer 123 may be formed by PVD process (e.g., sputter deposition), an atomic layer deposition (ALD) process, a PECVD process, other suitable deposition process, or the combination thereof. In some embodiments, the PVD process (e.g., sputter deposition) may be performed without using a hydrogen-containing precursor. Thus, the isolation layer 123 formed by sputter may have a hydrogen concentration less than 1%. In some alternative embodiments, the ALD process may be performed using a hydrogen-containing precursor (e.g., TMA) providing a less hydrogen content than that of the hydrogen-containing precursor (e.g., silane) used in the formation of silicon nitride. Thus, the isolation layer 123 formed by ALD may have a hydrogen concentration in a range from about 1% to about 2%. Details of the isolation layer 123 may be similar to that of the isolation layer 121. In some embodiment, the isolation layers 121 and 123 may include the same material. In some other embodiments, the isolation layers 121 and 123 may include different materials. After the formation of the isolation layer 123, a CMP process may be optionally performed to planarize a top surface of the isolation layer 123.

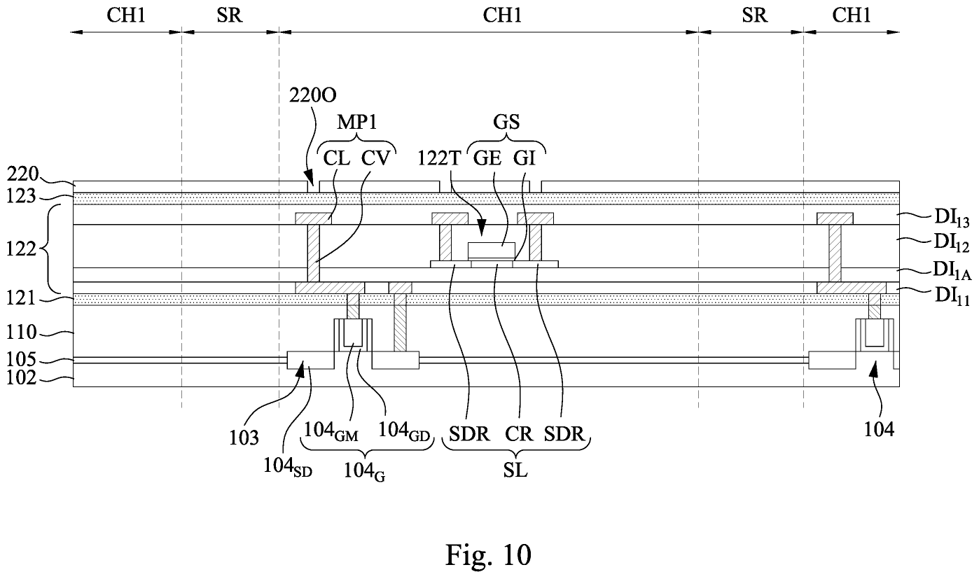

Reference is made to FIG. 10. A photoresist mask 220 is formed over the structure of FIG. 4 and exposing parts of the isolation layer 123. The photoresist mask 220 may include a photosensitive material. The photoresist mask 220 may be formed by suitable photolithography process, and have openings (or trenches) 220O therein. The photolithography process may include coating a photoresist layer (not shown), exposing the photoresist to a pattern, performing post-exposure bake processes, and developing the resist to form a patterned mask including the resist. In some alternative embodiments, the photoresist mask may be a tri-layer photoresist. For example, the photoresist mask 220 includes a bottom layer, a middle layer over the bottom layer, and a photoresist layer over the middle layer. The bottom layer may include organic or inorganic material. The middle layer may include silicon nitride, silicon oxynitride, SiOC, or the like. The photoresist layer may include a photosensitive material.

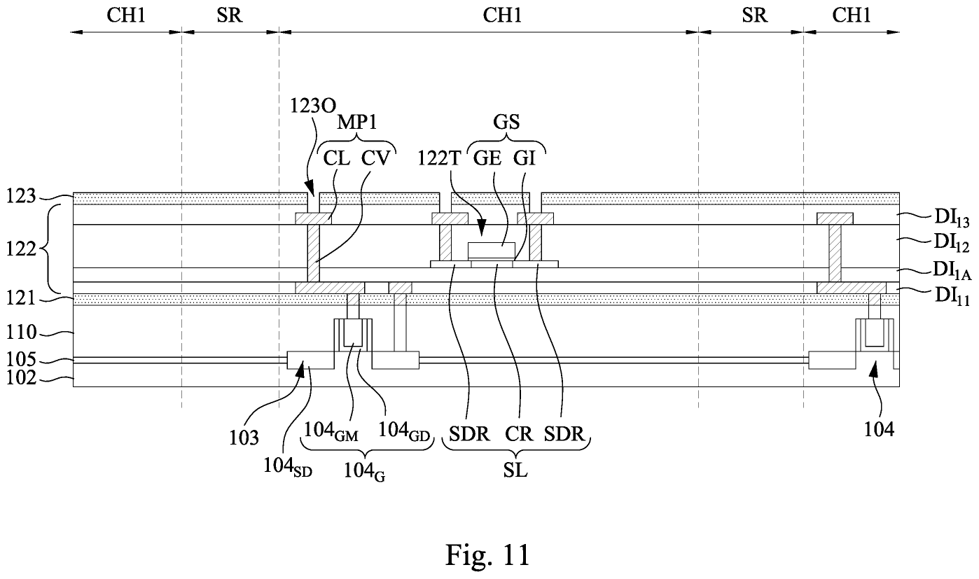

Reference is made to FIG. 11. The isolation layer 123 is patterned to have openings 123O exposing the underlying conductive features, such as conductive lines CL. In some embodiments, the isolation layer 123 is etched through the openings 220O of the photoresist mask 220 (referring to FIG. 10), thereby forming the openings 123O therein. The openings 123O may extend through the dielectric layer DI₁₃, thereby reaching the conductive lines CL. The patterning may include one or more etching processes. The etching process may include a dry etch process, a wet etch process, or the combination thereof. The photoresist mask 220 may serve as an etch mask during the etching process. After the etching process, the photoresist mask 220 may be stripped off by suitable ashing process.

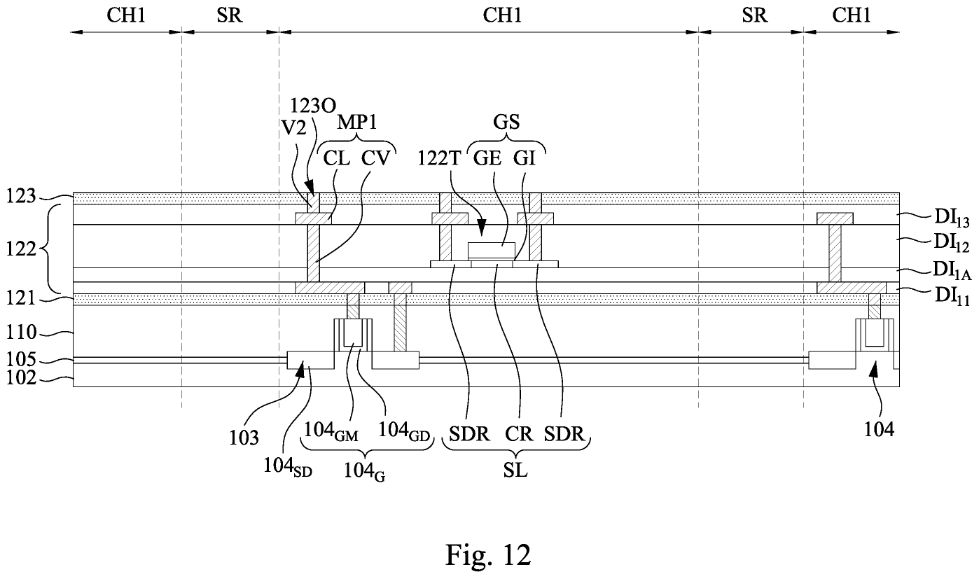

Reference is made to FIG. 12. Conductive vias V2 are formed in the openings 123O of the isolation layer 123 to connect the conductive lines CL. Formation of the conductive vias V2 may include filling the openings 123O with one or more conductive materials, followed by a CMP process to remove excess materials of the conductive materials. In some embodiments, the one or more conductive materials may include copper (Cu), tungsten (W), aluminum (Al), titanium (Ti), titanium nitride (TiN), and/or tantalum nitride (TaN). In some embodiments, one or more barrier/adhesion layers may be deposited into the openings 123O prior to depositing the one or more conductive materials. The one or more barrier/adhesion layers may comprise titanium, titanium nitride, tantalum, tantalum nitride, or the like, and may be formed using PVD, CVD, ALD, or the like.

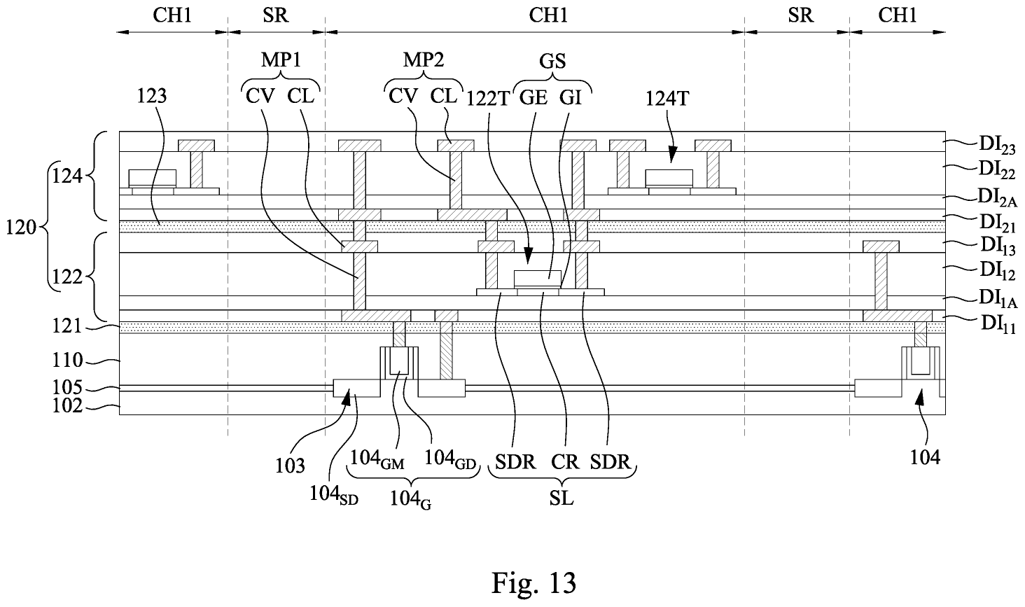

Reference is made to FIG. 13. A TFT-based interconnect structure 124 may be formed over the isolation layer 123. The TFT-based interconnect structure 124 may include multiple interconnect levels formed in the respective dielectric layers DI₂₁ to DI₂₃ using any suitable method, such as a single damascene process, a dual damascene process, or the like. The interconnect levels may include one or more horizontal interconnects, such as conductive lines CL, respectively extending horizontally or laterally in the dielectric layers DI₂₁ and DI₂₃ and vertical interconnects, such as conductive vias CV, extending vertically in the dielectric layer DI₂₂. A combination of the conductive lines CL and the conductive vias CV in these dielectric layers DI₂₁ to DI₂₃ can be referred to as the metallization pattern MP2.

In some embodiments, the TFT-based interconnect structure 124 may further include a TFT 124T surrounded by the dielectric layer DI₂₂. An additional dielectric layer DI_{2A} is formed over a metallization layer of TFT-based interconnect structure 124 (e.g., the dielectric layer DI₂₁ and the conductive line CL in the dielectric layer DI₂₁). The dielectric layer DI_{2A} serves as a base dielectric layer supporting the TFT 124T (e.g., the semiconductor layer SL). The fabrication process of the TFT 124T may include depositing a semiconductor layer SL over the dielectric layer DI_{2A}, patterning the semiconductor layer SL to have a suitable pattern, forming a gate structure GS over the semiconductor layer SL, and optionally doping the semiconductor layer SL to form the source/drain regions SDR. The formed TFT 124T is over the isolation layer 123, and spaced apart from the TFT 122T at least in part by the isolation layer 123. Other details regarding the materials and fabrication process of the TFT-based interconnect structure 124 and the TFT 124T are similar to those illustrated with the TFT-based interconnect structure 122 and the TFT 122T, and therefore not repeated herein.

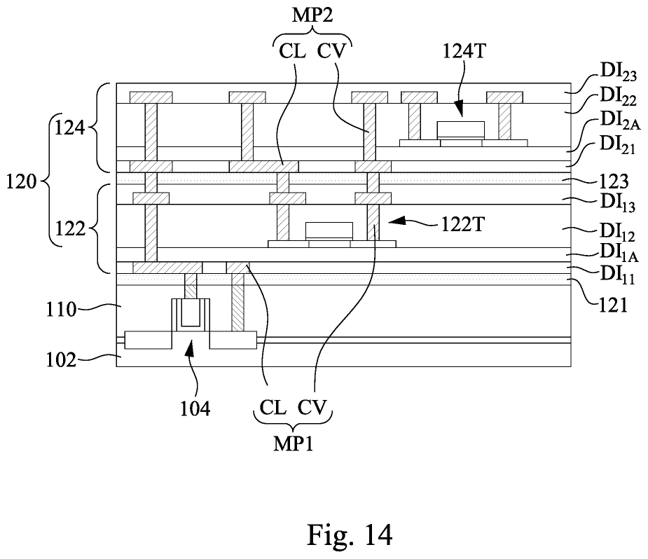

In FIGS. 8-14, a BEOL process is performed to form a BEOL interconnect structure 120 over the ILD layer 110, in which the BEOL interconnect structure 120 may include various TFT-based interconnect structures 122 and 124. After the BEOL process, a wafer dicing process may be performed on the dicing path region SR to singulate the chip regions CH1, thereby resulting in individual dies/chips shown in FIG. 14. The wafer dicing process may include suitable means for cutting the substrate 102 into the dies/chips. For example, the wafer dicing process can involve scribing and breaking, mechanical sawing, laser cutting, or the like.

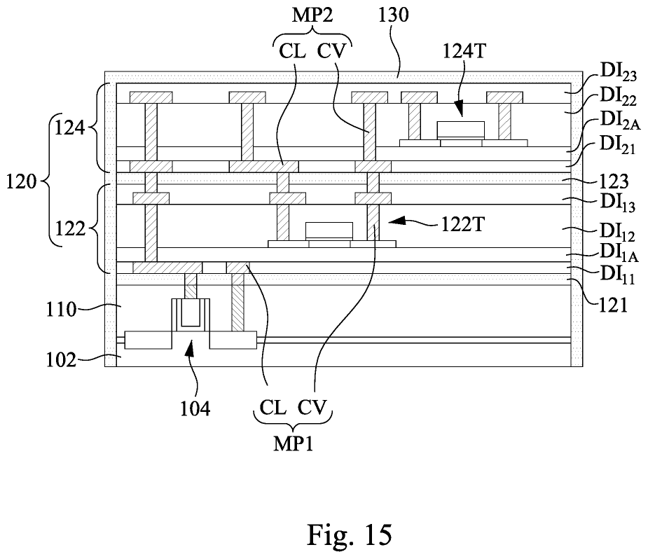

Reference is made to FIG. 15. Following wafer the dicing process the individual dies/chips may be encapsulated, and then suitable for use in building electronic devices such as computers, etc. An encapsulation layer 130 is formed around the die/chip shown in FIG. 14. The encapsulation layer 130 may include suitable materials for providing chemical and electrical isolations. In some embodiments, the encapsulation layer 130 may include ceramics. For example, the encapsulation layer 130 may include metal-containing compound materials, such as Al₂O₃, Zr₂O₃, TiO₂, the like, or the combination thereof. The encapsulation layer 130 and the isolation layer 121/123 may include the same material in some embodiments. In some other embodiments, the encapsulation layer 130 and the isolation layer 121/123 may include different materials.

In the present embodiments, the encapsulation layer 130 may be formed by a suitable deposition process using less or no hydrogen-containing precursor than the deposition process of silicon nitride, thereby having a lower hydrogen concentration than that of the silicon nitride layer. For example, the encapsulation layer 130 may be formed by a PVD process (e.g., sputter deposition), an atomic layer deposition (ALD) process, a PECVD process, other suitable deposition process, or the combination thereof. In some embodiments, the PVD process (e.g., sputter deposition) may be performed without using a hydrogen-containing precursor. Thus, the encapsulation layer 130 formed by sputter may have a hydrogen concentration less than 1%. In some alternative embodiments, the ALD process may be performed using a hydrogen-containing precursor (e.g., TMA) providing a less hydrogen content than that of the hydrogen-containing precursor (e.g., silane) used in the formation of silicon nitride. Thus, the encapsulation layer 130 formed by ALD may have a hydrogen concentration in a range from about 1% to about 2%. The encapsulation layer 130 may be a single layer, a multilayer stack, or a composite structure. For the encapsulation layer 130 having the composite structure, a co-sputtering process where two or more target (or source) materials are sputtered is performed to produce thin films that are combinatorial such as metal alloys or non-metallic compositions such as ceramics.

In some embodiments, the encapsulation layer 130 may have a thickness in a range from about 1 nanometer to about 1000 nanometers. If the thickness of the encapsulation layer 130 is less than about 1 nanometer, the encapsulation layer 130 may have poor film uniformity. If the thickness of the encapsulation layer 130 is greater than about 1000 nanometers, it unnecessarily increases process time and cost. The deposition temperature of the encapsulation layer 130 may be in a range from about 100 K to about 1000 K. If the deposition temperature of the encapsulation layer 130 is less than about 100K or greater than about 1000 K, it becomes difficult to form the isolation layer 121. Other details of the encapsulation layer 130 may be similar to that of the isolation layer 121/123, and thereto not repeated herein.

In absence of the encapsulation layer 130, moisture may diffuse into the devices through the dicing defects, resulting in high parasitic capacitance. Also, with moisture in the IMD/ILD, the breakdown voltage (VBD) of the IMD/ILD is lowered, and thus degrading the reliability of the in integrated circuit device.

In some embodiments of the present disclosure, the encapsulation layer 130 is formed on sidewalls and a top surface of dies/chips, thereby encapsulating the devices (e.g., the devices 104 and TFTs 122T and 124T). The encapsulation layer 130 can mitigate the moisture diffusion from the environment (side isolation) into the devices after wafer dicing. Through the configuration, the IMD/ILD are prevented from the moisture, and thus the breakdown voltage (VBD) of the IMD/ILD would not be lowered, which can improve the reliability of the in integrated circuit device.

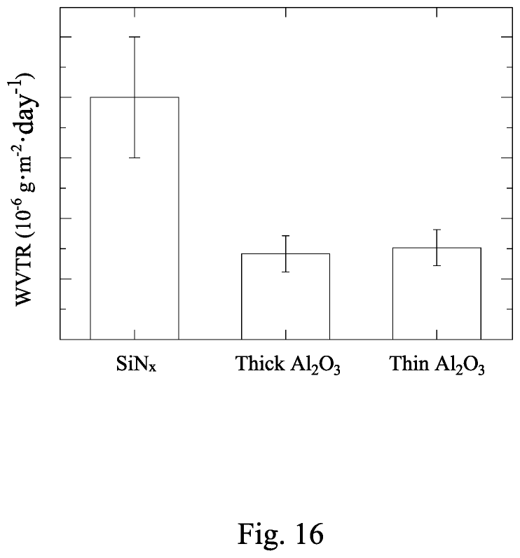

FIG. 16 is a graph of water vapor transmission rates (WVTR) of Al₂O₃ and silicon nitride according to some embodiments of the present disclosure. In the present embodiments, the thick Al₂O₃ and thin Al₂O₃ are formed by ALD process, and the thick Al₂O₃ may have a thickness greater than that of the thin Al₂O₃ but less than a thickness of the silicon nitride. In the figure, the WVTR of the thin Al₂O₃ is comparable to the WVTR of the thick Al₂O₃. Comparing the thick/thin Al₂O₃ with the silicon nitride, the thick/thin Al₂O₃ has a higher WVTR than that of the silicon nitride. As a result, the thick/thin Al₂O₃ can serve as the moisture-resistant isolation layer (e.g., the isolation layers 121, 123, and 125 in FIG. 1A) and the moisture-resistant encapsulation layer (e.g., the encapsulation layer 130 and 130′ in FIGS. 2A and 3).

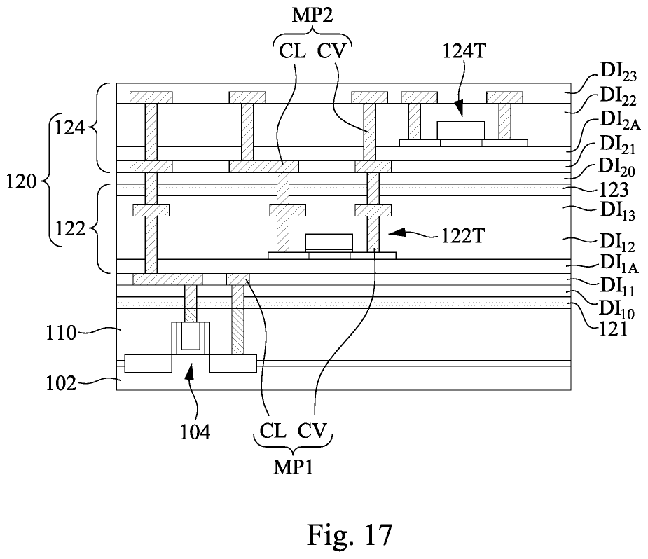

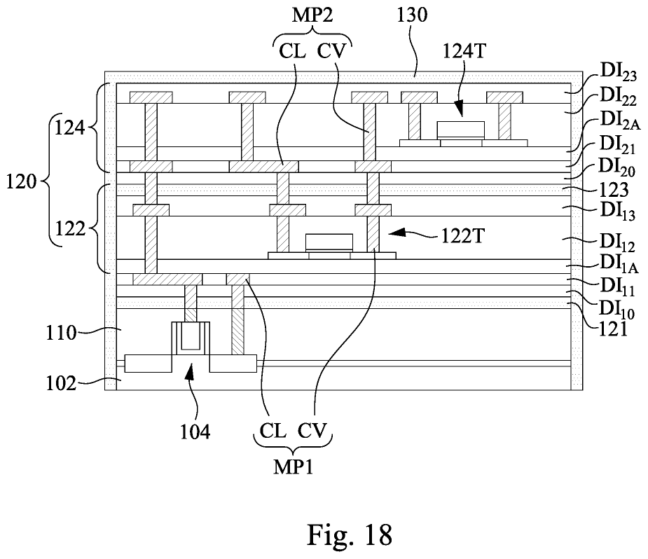

FIGS. 17 and 18 illustrate a method for fabricating an integrated circuit device at various intermediate stages of manufacture according to some embodiments of the present disclosure. The details of the present embodiments are similar to those of FIGS. 4-15, except that an additional dielectric layers DI₁₀ and DI₂₀ are formed over the isolation layers 121 and 123, thereby spacing the conductive lines CL apart from the isolation layers 121 and 123.

Reference is made to FIG. 17. A BEOL process is performed to form a BEOL interconnect structure 120 over the ILD layer 110, in which the BEOL interconnect structure 120 may include various TFT-based interconnect structures 122 and 124. In the present embodiments, for the TFT-based interconnect structure 122, prior to depositing the dielectric layer DI₁₁, a dielectric layer DI₁₀ may be deposited over a top surface of the isolation layer 121, and the conductive vias V1 are formed through the dielectric layer DI₁₁ and the isolation layer 121. In the present embodiments, for the TFT-based interconnect structure 124, prior to depositing the dielectric layer DI₂₁, a dielectric layer DI₂₀ may be deposited over a top surface of the isolation layer 123, and the conductive vias V2 are formed through the dielectric layer DI₂₀ and the isolation layer 123. In some embodiments, the dielectric layers DI₁₀ and DI₂₀ may include low-k dielectric materials having k values, for example, lower than about 4.0 or even 2.0 disposed between such conductive features. In some embodiments, the dielectric layers DI₁₀ and DI₂₀ may be made of, for example, PSG, BPSG, FSG, SiOₓC_{y}, Spin-On-Glass, Spin-On-Polymers, silicon oxide, silicon oxynitride, combinations thereof, or the like, formed by any suitable method, such as spin-on coating, CVD, PECVD, or the like. Through the configuration, the conductive lines CL in the dielectric layers DI₁₁ and DI₂₁ are spaced apart from the isolation layers 121 and 123. After the BEOL process, a wafer dicing process (e.g., using a saw, laser, or other device) may be performed to singulate the chip regions, thereby resulting in individual dies/chips shown in FIG. 17.

Reference is made to FIG. 18. An encapsulation layer 130 formed around the die/chip shown in FIG. 17 for providing chemical and electrical isolations. Other details of the present embodiments are similar to those illustrated with FIGS. 4-15, and thereto not repeated herein.

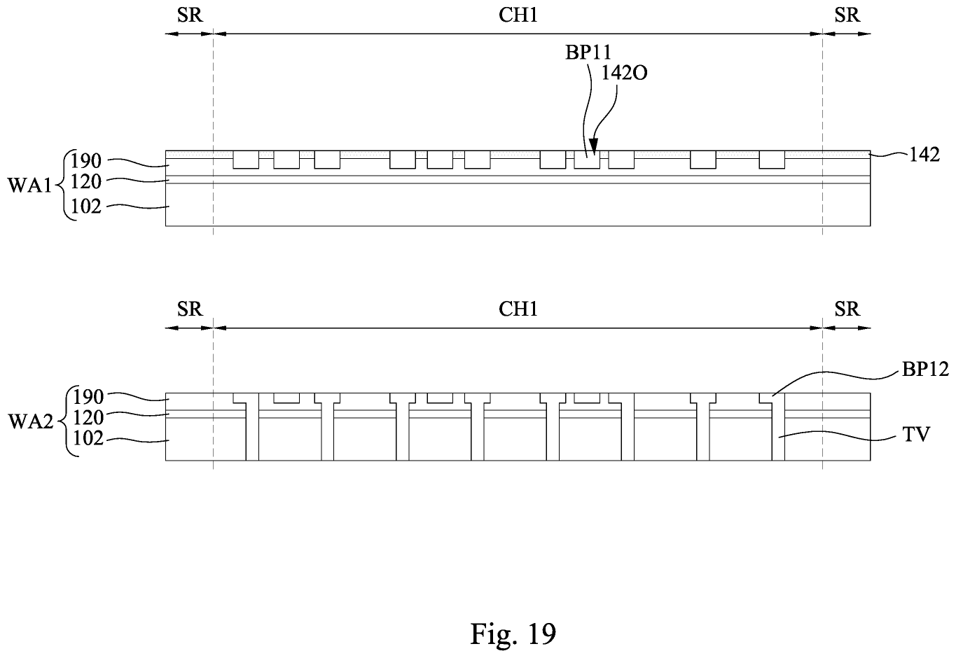

FIGS. 19-21 are exemplary cross-sectional views of an integrated circuit device according to some embodiments of the present disclosure. It is understood that additional operations may be provided before, during, and after the operations shown by FIGS. 19-21, and some of the operations described below can be replaced or eliminated for additional embodiments of the method. The order of the operations/processes may be interchangeable.

Referring to FIG. 19, wafers WA1 and WA2 are provided. In some embodiments, each of the wafers WA1 and WA2 may include a substrate 102, an interconnect structure 120 over the substrate 102, and a dielectric layer 190 over the interconnect structure 120. Each of the wafers WA1 and WA2 may include one or more chip regions CHI and a dicing path region SR surrounding the chip regions CH1. Details of the substrate 102 and the interconnect structure 120 of the wafers WA1 and WA2 may be similar to those of the aforementioned substrate and the aforementioned BEOL interconnect structure (e.g., the substrate 102 and the interconnect structure 120 of FIG. 13), and thereto not repeated herein.

In some embodiments, the dielectric layer 190 is an oxide layer, which may comprise silicon oxide. In other embodiments, the dielectric layer 190 comprises other silicon and/or oxygen containing materials such as SiON, SiN, or the like. Conductive connectors BP11 and BP12 may be formed in the dielectric layers 190, and may be electrically coupled to the metallization pattern of the interconnect structure 120 by suitable conductive features (e.g., vias). For example, the wafer WA2 include vias TV extending through the entire interconnect structure 120 and connecting the conductive connectors BP12 to the interconnect structure 120. Conductive connectors BP11 and BP12 may be formed of copper, aluminum, nickel, tungsten, or alloys thereof. In some embodiments, the conductive connectors BP11 and BP12 may be bond pads, metal pillars, the like, or the combination thereof. For wafer WA2, the dielectric layer 190 may be referred to as bond dielectric layers, and the top surface of the dielectric layer 190 and the top surfaces of the conductive connectors BP12 may be level with each other, which is achieved through a planarization that is performed during the formation of the conductive connectors BP12. The planarization may comprise a CMP process.

In the present embodiments, the wafer WA1 may further include an isolation layer 142 over the dielectric layer 190, and conductive connectors BP11 are formed in the dielectric layer 190 and the overlaying isolation layer 142. The isolation layer 142 may be referred to as a bond isolation layer. Material and formation of the isolation layer 142 may be similar to those of the isolation layers 121 and 123 (referring to FIGS. 4 and 12), and therefore not repeated herein. Formation of the conductive connectors BP11 may include etching an opening 142O in the isolation layer 142 and the underlying dielectric layer 190, and filling the opening 142O with a conductive material such as solder, copper, aluminum, gold, nickel, silver, palladium, tin, the like, or a combination thereof. A CMP process may be performed to remove a portion of the conductive material out of the opening 142O. For wafer WA1, the top surface of the isolation layer 142 and the top surfaces of the conductive connectors BP11 may be level with each other, which is achieved through the CMP process.

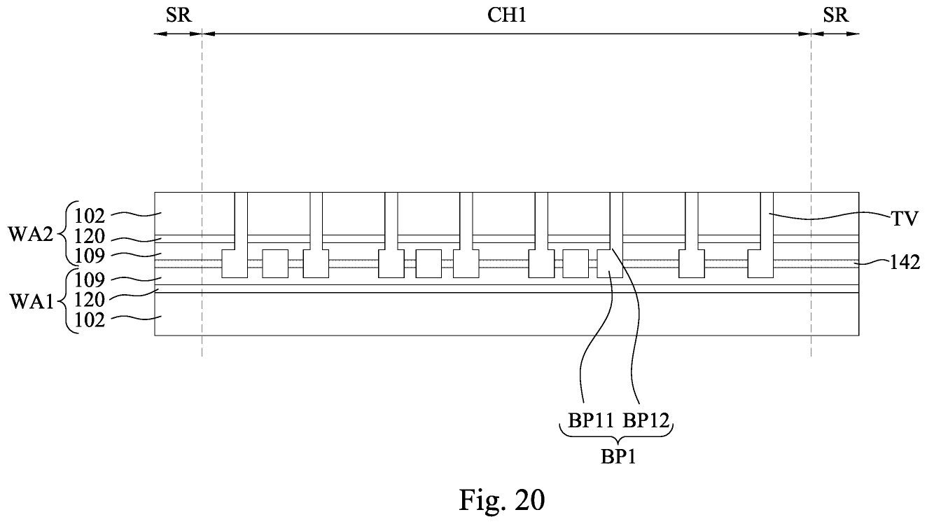

Referring to FIG. 20, the wafer WA2 is stacked vertically on the wafer WA1, for example, by wafer-on-wafer (WoW) techniques. In some embodiments, a hybrid bonding process is performed to bond wafer WA1 to the wafer WA2. The hybrid bonding process may include surface activation, thermal compression, and other suitable process. In some embodiments, the hybrid bonding process involves at least two types of bondings, including metal-to-metal (e.g., copper-to-copper) bonding and dielectric-to-dielectric bonding. For example, the conductive connectors BP12 of the wafer WA2 are bonded to the conductive connectors BP11 of the wafer WA1 by the metal-to-metal bonding, and the bond dielectric layer 190 of the wafer WA2 is bonded to the bond isolation layer 142 of the wafer WA1 by the dielectric-to-dielectric bonding. After the bonding process, the conductive connectors BP11 and BP12 in combination may be referred to as conductive connectors BP1. The conductive connectors BP1 may connect the metallization pattern of the interconnect structure 120 of the wafer WA2 to the metallization pattern of the interconnect structure 120 of the wafer WAI.

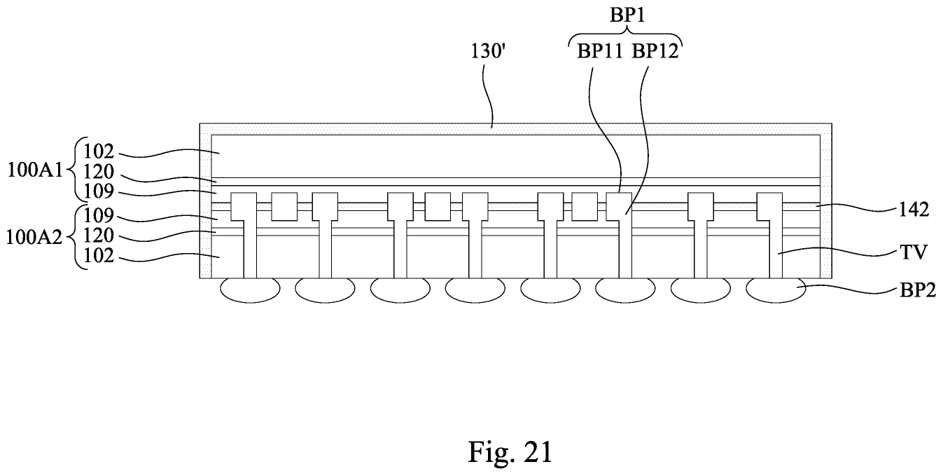

Referring to FIG. 21, after the bonding process, a wafer dicing process may be performed to dice the stacked wafers WA1 and WA2 along the dicing path region SR (referring to FIG. 20) for singulating the chip regions CH1 (referring to FIG. 20), thereby resulting in individual stacked dies/chips 100A1 and 100A2. The wafer dicing process may include suitable means for cutting the stacked wafers WA1 and WA2 into the stacked chips 100A1 and 100A2.

After the wafer dicing process, an encapsulation layer 130′ may be formed around the stacking chips 100A1 and 100A2. As aforementioned, the encapsulation layer 130′ may be made of suitable materials for providing chemical and electrical isolations. In some embodiments, the encapsulation layer 130′ may include ceramics. For example, the encapsulation layer 130′ may be made of metal-containing compound materials, such as Al₂O₃, Zr₂O₃, TiO₂, the like, or the combination thereof. The encapsulation layer 130′ may be formed by a PVD process (e.g., RF sputter), an atomic layer deposition (ALD) process, a PECVD process, other suitable deposition process, or the combination thereof. After the formation of the encapsulation layer 130′, solder balls BP2 may be disposed on a side of the chip 100A2 uncovered by the encapsulation layer 130′. The solder balls BP2 may be in contact with the via TV. The solder balls BP2 can be formed through evaporation, electroplating, printing, solder transfer, ball placement, or the like. Other details of the present embodiments are similar to those illustrated above, and thereto not repeated herein.

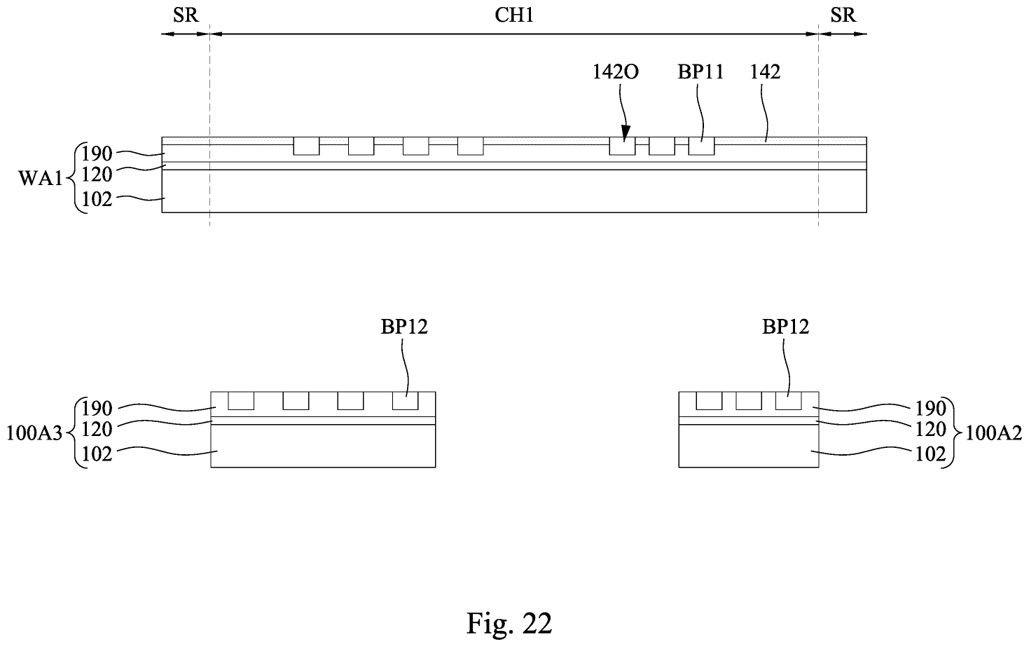

FIGS. 22-24 are an exemplary cross-sectional views of an integrated circuit device according to some embodiments of the present disclosure. Details of the present embodiments are similar to those illustrated in the embodiments of FIGS. 19-21, except that the IC device is formed using a chip-on-wafer (CoW) technique. It is understood that additional operations may be provided before, during, and after the operations shown by FIGS. 19-21, and some of the operations described below can be replaced or eliminated for additional embodiments of the method. The order of the operations/processes may be interchangeable.

Referring to FIG. 22, a wafer WA1, a chip 100A2, and a chip 100A3 are provided. The wafer WA1 may include a substrate 102, an interconnect structure 120 over the substrate 102, a dielectric layer 190 over the interconnect structure 120, an isolation layer 142 on the dielectric layer 190, and conductive connectors BP11. The conductive connectors BP11 may be formed in the dielectric layer 190 and the isolation layer 142. The wafer WA1 may include one or more chip regions CH1 and a dicing path region SR surrounding the chip regions CH1. Details of the wafer WAI are similar to those of the aforementioned wafer WA1 of FIG. 19, and thereto not repeated herein.

The chip 100A2 and the chip 100A3 may be formed from suitable wafers through wafer dicing processes. In some embodiments, each of the chip 100A2 and the chip 100A3 may include a substrate 102, an interconnect structure 120 over the substrate 102, and a dielectric layer 190 over the interconnect structure 120. Details of the substrate 102 and the interconnect structure 120 are similar to those aforementioned, and thereto not repeated herein. Conductive connectors BP12 may be formed in the dielectric layers 190, and may be electrically coupled to the metallization pattern of the interconnect structure 120.

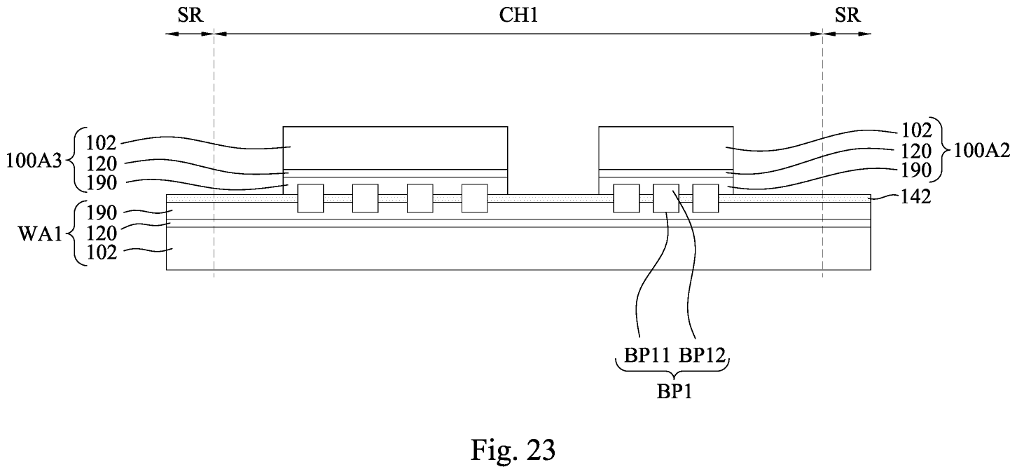

Referring to FIG. 23, the chips 100A2 and 100A3 are stacked vertically on the wafer WA1, for example, by CoW techniques. In some embodiments, one or more hybrid bonding processes are performed to bond the chips 100A2 and 100A3 to the wafer WA1. In some embodiments, the hybrid bonding process involves at least two types of bondings, including metal-to-metal (e.g., copper-to-copper) bonding and dielectric-to-dielectric bonding. For example, the conductive connectors BP12 of the chips 100A2/100A3 are bonded to the conductive connectors BP11 of the wafer WA1 by the metal-to-metal bonding, and the bond dielectric layer 190 of the chips 100A2/100A3 is bonded to the bond isolation layer 142 of the wafer WA1 by the dielectric-to-dielectric bonding. After the bonding process, the conductive connectors BP11 and BP12 in combination may be referred to as conductive connectors BPL The conductive connectors BPI may connect the metallization pattern of the interconnect structure 120 of the chip 100A2/100A3 to the metallization pattern of the interconnect structure 120 of the wafer WA1.

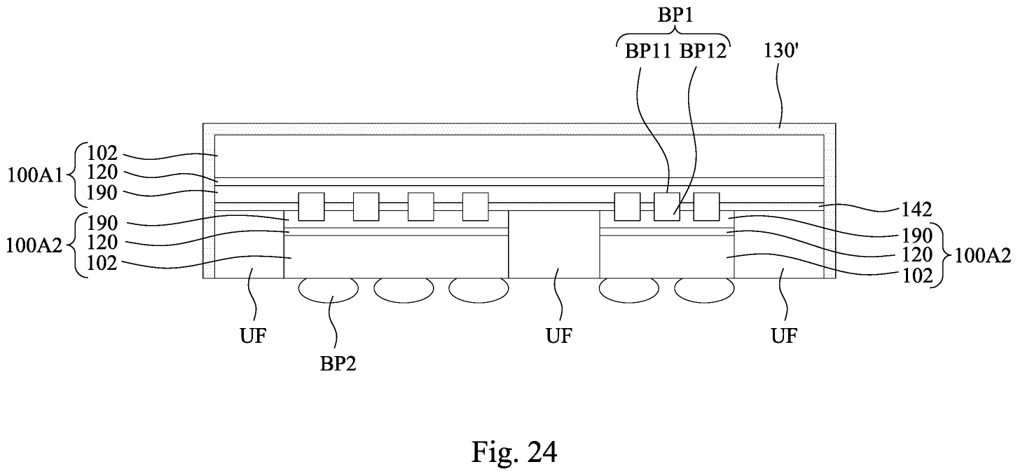

Referring to FIG. 24, after the bonding process, a wafer dicing process may be performed to dice the wafer WA1 along the dicing path region SR (referring to FIG. 23) for singulating the chip regions CH1 (referring to FIG. 23), thereby resulting in individual dies/chips 100A1 with chips 100A2 and 100A3 stacked thereon. The wafer dicing process may include suitable means for cutting the wafer WA1 into the chips 100A1. After the wafer dicing process, an underfill UF may be formed surrounding the chips 100A2 and 100A3. The underfill UF may provide structural support to the integrated circuit device. In some embodiments, the underfill UF may be a liquid epoxy that is dispensed between the chips 100A2-100A3, and then cured to harden, for example, by a thermal curing process. After the curing, the underfill UF is solidified. In some embodiments, the underfill UF includes an epoxy-based resin with fillers dispersed therein. The fillers may include fibers, particles, other suitable elements, a combination thereof, or the like. After the formation of the underfill UF, an encapsulation layer 130′ may then be formed around the chips 100A1-100A3, and solder balls BP2 may be disposed on sides of the chips 100A2 and 100A3 uncovered by the encapsulation layer 130′. Other details of the present embodiments are similar to those illustrated above, and thereto not repeated herein.

Based on the above discussions, it can be seen that the present disclosure offers advantages to the photonic package device. It is understood, however, that other embodiments may offer additional advantages, and not all advantages are necessarily disclosed herein, and that no particular advantage is required for all embodiments. One advantage is that TFTs can be easily stacked over CMOS devices due to the low processing temperature of TFTs. Another advantage is that a moisture-resistant isolation layer is disposed between stacked layers, thereby avoiding hydrogen and/or moisture diffusion to the stacked TFTs. Still another advantage is that a moisture-resistant encapsulation layer may be disposed around the stacked dies, thereby avoiding hydrogen and/or moisture diffusion.

According to some embodiments of the present disclosure, a method for fabricating an integrated circuit device is provided. The method includes forming a field effect transistor (FET) on a semiconductor substrate; depositing a first dielectric layer over the FET; depositing a first metal-containing dielectric layer over the first dielectric layer; and forming a first thin film transistor (TFT) over the first metal-containing dielectric layer.

According to some embodiments of the present disclosure, a method for fabricating an integrated circuit device is provided. The method includes forming a first transistor on a semiconductor substrate; depositing a first aluminum oxide layer over the first transistor; forming first vias in the first aluminum oxide layer; and after forming the first vias in the first aluminum oxide layer, forming a second transistor over the first aluminum oxide layer.

According to some embodiments of the present disclosure, an integrated circuit device includes a semiconductor substrate, a field effect transistor (FET), a first metal oxide layer, first metal vias, a first thin film transistor (TFT). The FET is on the semiconductor substrate. The first metal oxide layer is over the FET. The first metal vias are extending through the first metal oxide layer. The TFT is over the first metal oxide layer, and being spaced apart from the FET at least in part by the first metal oxide layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for fabricating an integrated circuit device, comprising:
forming a field effect transistor (FET) on a semiconductor substrate;
depositing a first dielectric layer over the FET;
depositing a first metal-containing dielectric layer over the first dielectric layer; and
forming a first thin film transistor (TFT) over the first metal-containing dielectric layer.

2. The method of claim 1, further comprising:
forming a conductive feature extending through the first metal-containing dielectric layer, wherein the conductive feature is electrically connected to the FET.

3. The method of claim 2, wherein forming the conductive feature comprises:
etching an opening in the first metal-containing dielectric layer; and
filling the opening with a conductive material.

4. The method of claim 1, further comprising:
depositing a second dielectric layer over the first TFT;
depositing a second metal-containing dielectric layer over the second dielectric layer; and
forming a second TFT over the second metal-containing dielectric layer.

5. The method of claim 4, further comprising:
forming a conductive feature extending through the second metal-containing dielectric layer, wherein the conductive feature is electrically connected to the first TFT.

6. The method of claim 1, wherein forming the FET comprises:
forming a gate dielectric in contact with a top surface of the semiconductor substrate; and
forming a gate electrode over the gate dielectric.

7. The method of claim 1, further comprising:
depositing a base dielectric layer over the first metal-containing dielectric layer prior to forming the first TFT, wherein forming the first TFT comprises forming a gate dielectric in contact with a top surface of the base dielectric layer and a gate electrode over the gate dielectric.

8. The method of claim I, wherein depositing the first metal-containing dielectric layer is performed using a sputter deposition process or an atomic layer deposition process.

9. The method of claim 1, further comprising:
dicing the semiconductor substrate into at least one chip; and
forming an encapsulation layer encapsulating the chip, wherein the encapsulation layer comprises a metal-containing dielectric material.

10. The method of claim 9, wherein the metal-containing dielectric material of the encapsulation layer is same as a material of the first metal-containing dielectric layer.

11. A method for fabricating an integrated circuit device, comprising:
forming a first transistor on a semiconductor substrate;
depositing a first aluminum oxide layer over the first transistor;
forming first vias in the first aluminum oxide layer; and
after forming the first vias in the first aluminum oxide layer, forming a second transistor over the first aluminum oxide layer.

12. The method of claim 11, wherein the first aluminum oxide layer is deposited by a radio frequency (RF) sputter deposition process without using a hydrogen-containing precursor.

13. The method of claim 11, wherein the first aluminum oxide layer is deposited by an atomic layer deposition (ALD) process.

14. The method of claim 11, further comprising:
depositing a second aluminum oxide layer over the second transistor;
forming second vias in the second aluminum oxide layer; and
after forming the second vias in the second aluminum oxide layer, forming a third transistor over the second aluminum oxide layer.

15. The method of claim 14, further comprising:
encapsulating the first, second, and third transistors in a third aluminum oxide layer.

16. An integrated circuit device, comprising:
a semiconductor substrate;
a field effect transistor (FET) on the semiconductor substrate;
a first metal oxide layer over the FET;
first metal vias extending through the first metal oxide layer; and
a first thin film transistor (TFT) over the first metal oxide layer, the first TFT being spaced apart from the FET at least in part by the first metal oxide layer.

17. The integrated circuit device of claim 16, further comprising:
an encapsulation layer encapsulating the FET and the first TFT.

18. The integrated circuit device of claim 17, wherein the encapsulating layer is made of a same material as the first metal oxide layer.

19. The integrated circuit device of claim 17, wherein the encapsulating layer is made of aluminum oxide.

20. The integrated circuit device of claim 16, further comprising:
a second metal oxide layer over the first TFT;
second metal vias extending through the second metal oxide layer; and
a second TFT over the second metal oxide layer, the second TFT being spaced apart from the first TFT at least in part by the second metal oxide layer.
